(19) United States
(12) Patent Application Publication
(10) Pub. No.: US 2026/0090175 A1
(43) Pub. Date: Mar. 26, 2026

(54) DISPLAY DEVICE AND ELECTRONIC DEVICE INCLUDING THE SAME

(71) Applicant: Samsung Display Co., Ltd., Yongin-si (KR)

(72) Inventors: Dokyung Youn, Yongin-si (KR); Cheol Shin, Yongin-si (KR); Jiseong Yang, Yongin-si (KR); Keunchan Oh, Yongin-si (KR); Songee Lee, Yongin-si (KR); Sunkyu Joo, Yongin-si (KR); Wooman Ji, Yongin-si (KR); Taehyung Hwang, Yongin-si (KR)

(21) Appl. No.: 19/232,267

(22) Filed: Jun. 9, 2025

(30) Foreign Application Priority Data
Sep. 25, 2024 (KR) 10-2024-0130210

(51) Int. Cl. H10H 29/855; H10H 29/85; H10H 29/851; H10H 29/852; H10K 59/38; H10K 59/80; H10K 102/00

(52) U.S. Cl. CPC H10H 29/855; H10H 29/8512; H10H 29/8517; H10H 29/852; H10K 59/38; H10K 59/873; H10K 59/879; H10K 2102/331

(57) ABSTRACT

A display device includes a first substrate, a second substrate opposite to the first substrate, a light-emitting element layer on the first substrate and including at least one light-emitting element, an encapsulation layer on the light-emitting element layer and including at least one inorganic encapsulation layer and at least one organic encapsulation layer, a functional layer on the encapsulation layer and including at least one of quantum dots or scattering particles, a color filter layer on a surface of the second substrate facing the first substrate, a lens layer on a surface of the color filter layer facing the functional layer and corresponding to the at least one light-emitting element, and a low-refractive layer between the color filter layer and the lens layer on the second substrate and the functional layer on the first substrate.

### CROSS-REFERENCE TO RELATED APPLICATION

The present application claims priority to and the benefit of Korean Patent Application No. 10-2024-0130210, filed on Sep. 25, 2024, in the Korean Intellectual Property Office, the entire disclosure of which is incorporated herein by reference.

### BACKGROUND

### 1. Field

One or more embodiments of the present disclosure relate to a display device.

### 2. Description of the Related Art

Due to rapid developments in the field of display devices, i.e., devices for visually expressing various pieces of electrical signal information, certain display devices with extraordinary characteristics, such as small thickness, small weight, and/or low power consumption, have been introduced.

Such display devices may include liquid crystal display devices (LCD) devices, which rely on external light sources, such as backlight units, to produce visible images. These devices do not generate light on their own but modulate the light passing through them to create the desired visual output. In contrast, light-emitting display devices, such as organic light-emitting diode (OLED) displays, contain light-emitting elements that produce light independently. These elements include emission layers that generate light.

The above information disclosed in this Background section is intended to enhance understanding of the background of the disclosure and may contain information that does not constitute prior art.

### SUMMARY

Aspects of one or more embodiments of the present disclosure are directed toward a display device with enhanced (e.g., improved) light efficiency. However, the embodiments are examples and do not limit the scope of the disclosure.

Additional aspects will be set forth in part in the description which follows and, in part, will be apparent from the description, or may be learned by practice of the presented embodiments of the disclosure.

According to one or more embodiments of the present disclosure, a display device includes a first substrate, a second substrate opposite to the first substrate, a light-emitting element layer arranged on the first substrate and including at least one light-emitting element, an encapsulation layer arranged on the light-emitting element layer and including at least one inorganic encapsulation layer and at least one organic encapsulation layer, a functional layer arranged on the encapsulation layer and including at least one of quantum dots and/or scattering particles, a color filter layer arranged on a surface of the second substrate facing (e.g., opposite to) the first substrate, and a lens layer arranged on a surface of the color filter layer facing (e.g., opposite to) the functional layer and corresponding to the at least one light-emitting element, and a low-refractive layer arranged between the color filter layer and the lens layer on the second substrate and the functional layer on the first substrate. For example, the “low-refractive layer” is positioned between the color filter layer and the lens layer on the second substrate on one side, and the functional layer on the first substrate on the other side. For example, this refers to that the low-refractive layer is sandwiched between these two sides, helping to manage light refraction and improve the display's visual quality.

In one or more embodiments, the low-refractive layer may be in direct contact with the lens layer, and a refractive index of the low-refractive layer may be less than a refractive index of the lens layer.

In one or more embodiments, a difference between the refractive index of the lens layer and the refractive index of the low-refractive layer may be in a range of about 0.2 to about 0.75.

In one or more embodiments, the lens layer may include a plurality of lenses, wherein each of the plurality of lenses may have a convex shape in a direction opposite to the direction from which light is to be emitted from the at least one light-emitting element.

In one or more embodiments, a surface of the lens layer in contact with the low-refractive layer may include convex surfaces of the plurality of lenses and flat surfaces between the convex surfaces.

In one or more embodiments, six lenses of the plurality of lenses may be arranged at equal intervals around another lens of the plurality of lenses in a plan view. For example, this refers to that in a top-down view, one lens is surrounded by six other lenses, each spaced equally apart from one another, forming a symmetrical pattern.

In one or more embodiments, an interval between two adjacent lenses among the plurality of lenses may be in a range of about 2 μm to about 3 μm.

In one or more embodiments, a diameter of each of the plurality of lenses may be in a range of about 3 μm to about 4 μm.

In one or more embodiments, the plurality of lenses may include a first lens positioned at a center of the at least one light-emitting element and a second lens positioned at a periphery of the at least one light-emitting element in a plan view.

In one or more embodiments, a curvature of a convex surface of the second lens may be less than a curvature of a convex surface of the first lens.

In one or more embodiments, the encapsulation layer may include a first inorganic encapsulation layer, an organic encapsulation layer, and a second inorganic encapsulation layer sequentially arranged, and the functional layer may be direct contact the second inorganic encapsulation layer.

In one or more embodiments, the light-emitting element layer may include a first light-emitting element, a second light-emitting element, and a third light-emitting element, and the functional layer may include a first quantum-dot layer corresponding to the first light-emitting element, a second quantum-dot layer corresponding to the second light-emitting element, and a light transmission layer corresponding to the third light-emitting element.

In one or more embodiments, the color filter layer may include a first color filter corresponding to the first light-emitting element, a second color filter corresponding to the second light-emitting element, and a third color filter corresponding to the third light-emitting element, and at least two color filters selected from among the first color filter, the second color filter, and the third color filter may overlap each other to define a light-blocking portion.

In one or more embodiments, the lens layer may include a first lens layer corresponding to the first light-emitting element, a second lens layer corresponding to the second light-emitting element, and a third lens layer corresponding to the third light-emitting element, and the first lens layer, the second lens layer, and the third lens layer may not overlap the light-blocking portion of the color filter layer.

In one or more embodiments, the display device may further include a spacer arranged on the surface of the color filter layer facing (e.g., opposite to) the functional layer, wherein the spacer may include the same material as the lens layer.

In one or more embodiments, the display device may further include a filler arranged between the low-refractive layer and the functional layer.

In one or more embodiments, the display device may further include a first passivation layer arranged between the functional layer and the filler, and a second passivation layer arranged between the low-refractive layer and the filler.

In one or more embodiments, the low-refractive layer may be a layer of air defining an air gap between the lens layer and the functional layer.

According to one or more embodiments of the present disclosure, a display device includes a first substrate, a second substrate opposite to the first substrate, a light-emitting element layer arranged on the first substrate and including at least one light-emitting element, an encapsulation layer arranged on the light-emitting element layer and including at least one inorganic encapsulation layer and at least one organic encapsulation layer, a functional layer arranged on the encapsulation layer and including at least one of quantum dots and/or scattering particles, a color filter layer arranged on a surface of the second substrate facing (e.g., opposite to) the first substrate, and a lens layer arranged on a surface of the color filter layer facing (e.g., opposite to) the functional layer and corresponding to the at least one light-emitting element, wherein the lens layer is spaced and/or apart (e.g., spaced apart or separated) from the functional layer with an air gap therebetween.

In one or more embodiments, the lens layer may include a plurality of lenses, wherein each of the plurality of lenses may have a convex shape in a direction opposite to a direction from which light is to be emitted from the at least one light-emitting element.

In one or more embodiments, a surface of the lens layer in contact with the air gap may include convex surfaces of the plurality of lenses and flat surfaces between the convex surfaces.

In one or more embodiments, the plurality of lenses may include a first lens positioned at a center of the at least one light-emitting element and a second lens positioned at a periphery of the at least one light-emitting element in a plan view.

In one or more embodiments, a curvature of a convex surface of the second lens may be less than a curvature of a convex surface of the first lens.

In one or more embodiments, the display device may further include a spacer arranged on the surface of the color filter layer facing (e.g., opposite to) the functional layer, wherein the spacer may include the same material as the lens layer.

According to one or more embodiments of the present disclosure, an electronic device includes display device including a first substrate, a second substrate opposite to the first substrate, a light-emitting element layer arranged on the first substrate and including at least one light-emitting element, an encapsulation layer arranged on the light-emitting element layer and including at least one inorganic encapsulation layer and at least one organic encapsulation layer, a functional layer arranged on the encapsulation layer and including at least one of quantum dots and/or scattering particles, a color filter layer arranged on a surface of the second substrate facing (e.g., opposite to) the first substrate, and a lens layer arranged on a surface of the color filter layer facing (e.g., opposite to) the functional layer and corresponding to the at least one light-emitting element, and a low-refractive layer arranged between the color filter layer and the lens layer on the second substrate and the functional layer on the first substrate.

In one or more embodiments, the electronic device may be a television, a billboard, a cinema screen, a monitor, a tablet PC, or a laptop.

In one or more embodiments, the electronic device may further include a display module; a processor; a power module; and a memory, wherein the display device may include one of the display module, the processor, the power module, or the memory.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a schematic perspective view of a display device according to one or more embodiments of the present disclosure;

FIG. 2 is a schematic cross-sectional view of a sub-pixel of a display device according to one or more embodiments of the present disclosure;

FIG. 3 is a schematic diagram showing optical layers of a functional layer of FIG. 2, according to one or more embodiments of the present disclosure;

FIG. 4 is an equivalent circuit diagram of a light-emitting element included in a display device and a sub-pixel circuit electrically connected to the light-emitting element, according to one or more embodiments of the present disclosure;

FIG. 5 is a schematic cross-sectional view of the display device taken along the line A-A′ of FIG. 1, according to one or more embodiments of the present disclosure;

FIG. 6 is an enlarged cross-sectional view schematically illustrating the region X of FIG. 5, according to one or more embodiments of the present disclosure;

FIG. 7 is a graph showing refractive indices of a lens layer and a low-refractive layer included in a display device according to one or more embodiments of the present disclosure;

FIG. 8 is a schematic plan view of a lens layer included in a display device according to one or more embodiments of the present disclosure;

FIG. 9 is a schematic cross-sectional view schematically illustrating the region X of FIG. 5, according to one or more embodiments of the present disclosure;

FIG. 10 is a schematic cross-sectional view of a display device taken along the line A-A′ of FIG. 1, according to one or more embodiments of the present disclosure;

FIG. 11 is a schematic cross-sectional view of a display device taken along the line A-A′ of FIG. 1, according to one or more embodiments of the present disclosure;

FIG. 12 is a schematic cross-sectional view of a display device taken along the line A-A′ of FIG. 1, according to one or more embodiments of the present disclosure;

FIG. 13 is an enlarged cross-sectional view schematically illustrating the region X′ of FIG. 12, according to one or more embodiments of the present disclosure;

FIG. 14 is an enlarged cross-sectional view schematically illustrating the region X′ of FIG. 12, according to one or more embodiments of the present disclosure;

FIG. 15 is a schematic cross-sectional view of a display device taken along the line A-A′ of FIG. 1, according to one or more embodiments of the present disclosure;

FIG. 16 is a block diagram of an electronic device according to an one or more embodiments of the present disclosure; and

FIG. 17 is schematic diagrams of electronic devices according to various embodiments.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals denote like elements throughout the attached drawings and the written description, and thus, duplicative descriptions thereof may not be provided.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present.

In the drawings, the relative sizes of elements, layers, and regions may be exaggerated or reduced for convenience of explanation. For example, the size and thickness of each element shown in the drawings may be arbitrarily represented for convenience of description, and thus, the disclosure is not necessarily limited thereto.

In the case where a certain embodiment may be implemented differently, a specific process order may be performed in the order different from the described order. For example, two processes successively described may be substantially concurrently (e.g., substantially simultaneously) performed or performed in the opposite order.

In the present specification, “A and/or B” refers to A or B, or A and B. In the present specification, “at least one of A and B” refers to A or B, or A and B.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element located therebetween.

The x-axis, the y-axis and the z-axis are not limited to three axes of the rectangular coordinate system, and may be interpreted in a broader sense. For example, the x-axis, the y-axis, and the z-axis may be normal (e.g., perpendicular) to one another, or may represent different orientations that are not normal (e.g., perpendicular) to one another.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the z-axis direction refers to a top-down view of the display panel, as if looking directly down onto the surface from above. In this context, the z-axis direction is the direction perpendicular or normal to the plane defined by the x-axis direction and the y-axis direction. This refers to that in a plan view, the arrangement of sub-pixels, pads, and other components as they are laid out on the substrate can be seen, without any perspective distortion.

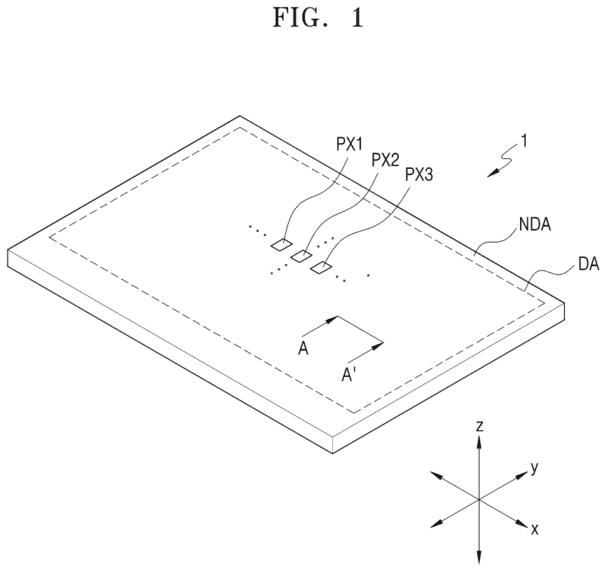

FIG. 1 is a schematic perspective view of a display device 1 according to one or more embodiments of the present disclosure.

Referring to FIG. 1, the display device 1 may include a display area DA that is to implement an image and a non-display area NDA that does not implement an image. The display device 1 may provide an image through an array of a plurality of sub-pixels arranged two-dimensionally on an x-y plane in the display area DA. The plurality of sub-pixels may be to emit light of different colors, and each of the plurality of sub-pixels may be one of, for example, a red sub-pixel, a green sub-pixel, or a blue sub-pixel.

In one or more embodiments, the plurality of sub-pixels may include a first sub-pixel PX1, a second sub-pixel PX2, and a third sub-pixel PX3. For convenience of explanation, it is assumed that the first sub-pixel PX1 is a red sub-pixel, the second sub-pixel PX2 is a green sub-pixel, and the third sub-pixel PX3 is a blue sub-pixel.

The first sub-pixel PX1, the second sub-pixel PX2, and the third sub-pixel PX3 are areas that may be to emit red light, green light, and blue light, respectively, and the display device 1 may provide an image using the light emitted from the plurality of sub-pixels.

The non-display area NDA is an area that does not provide an image and may be entirely around (e.g., surround) the display area DA. A driver or a main power line configured to provide electrical signals or power to sub-pixel circuits may be arranged in the non-display area NDA. The non-display area NDA may include a pad, that is, an area to which electronic devices or a printed circuit board may be electrically connected.

The display area DA may have a polygonal shape, for example, a rectangle as illustrated in FIG. 1. For example, the display area DA may have a rectangular shape with a horizontal length greater than a vertical length, a rectangular shape with a horizontal length less than a vertical length, or a square shape. In other embodiments, the display area DA may be a circle, an ellipse, or a polygon, such as a triangle or pentagon. In one or more embodiments, the display device 1 illustrated in FIG. 1 is a flat display device, and the display device 1 may be implemented as a flexible, foldable, or rollable display device.

In one or more embodiments, the display device 1 may be an organic light-emitting display device. In one or more embodiments, the display device 1 may be an inorganic light-emitting display device or a quantum dot light-emitting display device. For example, an emission layer of a display element included in the display device 1 may include an organic material, an inorganic material, quantum dots, an organic material and quantum dots, an inorganic material and quantum dots, or an organic material, an inorganic material, and quantum dots. For convenience of explanation, it is assumed in the following description that the display device 1 is an organic light-emitting display device.

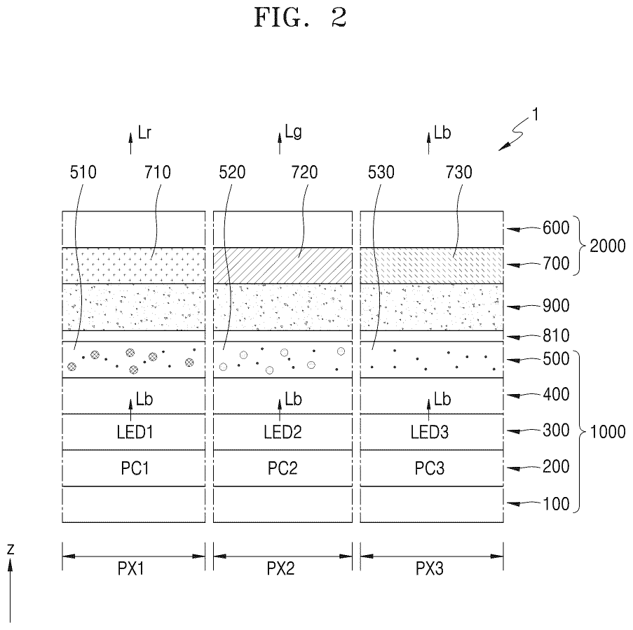

FIG. 2 is a schematic cross-sectional view of a sub-pixel of the display device 1 according to one or more embodiments of the present disclosure.

Referring to FIG. 2, the display device 1 may include a light-emitting panel 1000 and a color filter panel 2000 that are spaced and/or apart (e.g., spaced apart or separated) from each other in a thickness direction (e.g., a z direction). In one or more embodiments, as illustrated in FIG. 2, a filler 900 may be arranged between the light-emitting panel 1000 and the color filter panel 2000. However, the present disclosure is not necessarily limited thereto. In one or more embodiments, the light-emitting panel 1000 and the color filter panel 2000 may be positioned with an air gap therebetween.

The light-emitting panel 1000 of the display device 1 may include, as shown in FIG. 2, a circuit layer 200 on a first substrate 100, a light-emitting element layer 300 on the circuit layer 200, an encapsulation layer 400 on the light-emitting element layer 300, a functional layer 500 on the encapsulation layer 400, and a first passivation layer 810 on the functional layer 500.

The circuit layer 200 may include first to third sub-pixel circuits PC1, PC2, and PC3, and each of the first to third sub-pixel circuits PC1, PC2, and PC3 may include a thin film transistor and/or a capacitor. The first to third sub-pixel circuits PC1, PC2, and PC3 may be electrically connected to the first to third light-emitting elements LED1, LED2, and LED3 of the light-emitting element layer 300, respectively.

The first to third light-emitting elements LED1, LED2, and LED3 may each include organic light-emitting diodes including organic materials. In one or more embodiments, the first to third light-emitting elements LED1, LED2, and LED3 may be inorganic light-emitting diodes including inorganic materials. The inorganic light-emitting diode may include a PN junction diode including inorganic semiconductor-based materials. When a voltage is applied in a positive direction to the PN junction diode, holes and electrons are injected into the PN junction diode, and energy generated by recombination of the holes and electrons may be converted into light energy to emit light having a certain color. The inorganic light-emitting diode may have a width of about several micrometers to hundreds of micrometers, or several micrometers to hundreds of nanometers. In one or more embodiments, the first to third light-emitting elements LED1, LED2, and LED3 may be light-emitting diodes including quantum dots. As described above, the emission layers of the first to third light-emitting elements LED1, LED2, and LED3 may include an organic material, an inorganic material, quantum dots, an organic material and quantum dots, an inorganic material and quantum dots, or an organic material, an inorganic material, and quantum dots.

The first to third light-emitting elements LED1, LED2, and LED3 may be to emit light of the same color. For example, light (e.g., blue light Lb) emitted from the first to third light-emitting elements LED1, LED2, and LED3 may pass through the encapsulation layer 400 on the light-emitting element layer 300 and the functional layer 500. However, the present disclosure is not limited thereto. In one or more embodiments, the first to third light-emitting elements LED1, LED2, and LED3 may be to emit light of different colors.

The functional layer 500 may include optical layers that convert or transmit the color of light (e.g., blue light Lb) emitted from the light-emitting element layer 300 without conversion. For example, the functional layer 500 may include quantum-dot layers configured to convert the light (e.g., blue light Lb) emitted from the light-emitting element layer 300 into light of a different color, and may include a light transmission layer configured to transmit the light (e.g., blue light Lb), which is emitted from the light-emitting element layer 300, without color conversion. The functional layer 500 may include a first quantum-dot layer 510 corresponding to the first sub-pixel PX1, a second quantum-dot layer 520 corresponding to the second sub-pixel PX2, and a light transmission layer 530 corresponding to the third sub-pixel PX3. The first quantum-dot layer 510 may convert blue light Lb into red light Lr, and the second quantum-dot layer 520 may convert blue light Lb into green light Lg. The light transmission layer 530 may be to transmit the blue light Lb without conversion.

The functional layer 500 may be formed above the first substrate 100 rather than above the second substrate 600. In such embodiments, the functional layer 500 may be arranged on the encapsulation layer 400 to directly contact the encapsulation layer 400. Accordingly, a distance between the first to third light-emitting elements LED1, LED2, and LED3 and the functional layer 500 may be reduced, and loss of light in a path may be reduced as much as possible to thus improve light efficiency.

The color filter panel 2000 may include a color filter layer 700 arranged on a surface of the second substrate 600 facing (e.g., opposite to) the first substrate 100. In one or more embodiments, the color filter layer 700 may be arranged to face the functional layer 500 with the filler 900 therebetween. The color filter layer 700 may include first to third color filters 710, 720, and 730 of different colors. In one or more embodiments, the first color filter 710 may be a red color filter, the second color filter 720 may be a green color filter, and the third color filter 730 may be a blue color filter.

Color purities of lights converted and transmitted by the functional layer 500 may be improved by the first to third color filters 710, 720, and 730. In one or more embodiments, the color filter layer 700 may prevent, minimize or reduce external light (e.g., light incident on the display device 1 from outside the display device 1) from being reflected and recognized by a user.

The filler 900 may be arranged between the functional layer 500 and the color filter layer 700. The filler 900 may fill in the space between the light-emitting panel 1000 and the color filter panel 2000 after the light-emitting panel 1000 and the color filter panel 2000 are bonded together by a sealant. The filler 900 may include a light-transmitting material for example, an acrylic resin or an epoxy resin. In one or more embodiments, a refractive index of the filler 900 may be in a range of about 1.45 to about 1.55.

The display device 1 having the structure described above may be used in an electronic device capable of displaying a moving image and/or a still image, such as a television, a billboard, a cinema screen, a monitor, a tablet PC, or a laptop.

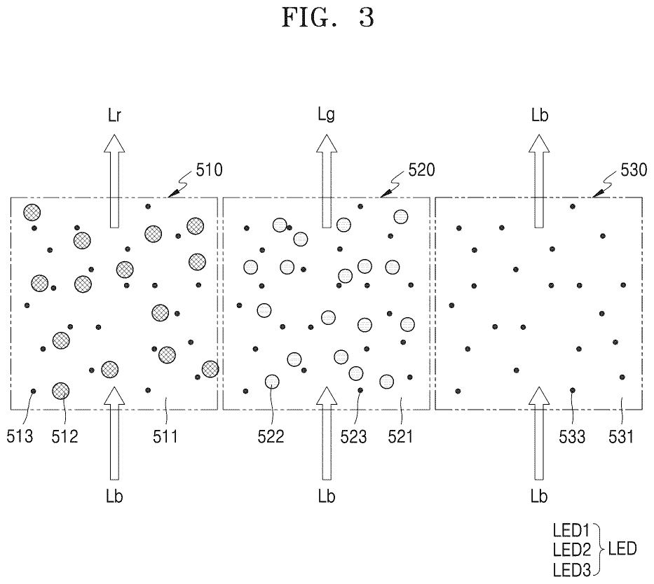

FIG. 3 is a schematic diagram showing optical layers of the functional layer of FIG. 2, according to one or more embodiments of the present disclosure.

Referring to FIG. 3, the first quantum-dot layer 510 may convert the blue light Lb incident thereon into the red light Lr. The first quantum-dot layer 510 may include a first photosensitive polymer 511, and first quantum dots 512 and first scattering particles 513 may be dispersed in the first photosensitive polymer 511.

The first quantum dots 512 may be excited by the blue light Lb to emit the red light Lr having a wavelength greater than a wavelength of the blue light Lb. The first photosensitive polymer 511 may include an organic material having light transmissivity.

The first scattering particles 513 may scatter the blue light Lb that has not been absorbed by the first quantum dots 512 to excite more of the first quantum dots 512, and thus the first scattering particles 513 may increase the efficiency of color conversion. The first scattering particles 513 may include, for example, titanium dioxide (TiO₂) particles and/or metal particles. The first quantum dots 512 may be selected from among a Group II-VI compound, a Group III-V compound, a Group IV-VI compound, a Group IV element, a Group IV compound, and/or a (e.g., any suitable) combination(s) thereof.

The Group II-VI compound may be selected from a group consisting of a two-element compound selected from a group consisting of CdSe, CdTe, ZnS, ZnSe, ZnTe, ZnO, HgS, HgSe, HgTe, MgSe, MgS and/or a (e.g., any suitable) combination(s) thereof; a three-element compound selected from a group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or a (e.g., any suitable) combination(s) thereof; and a four-element compound selected from a group consisting of HgZnTeS, CdZnSeS, CdZnSeTe, CdZnSTe, CdHgSeS, CdHgSeTe, CdHgSTe, HgZnSeS, HgZnSeTe, HgZnSTe, and/or a (e.g., any suitable) combination(s) thereof.

The Group III-VI compound may include: a two-element compound such as In₂S₃, In₂Se₃; a three-element compound such as InGaSe, InGaSe₃; and/or an arbitrary combination thereof.

The Group III-V compound may be selected from a group consisting of: a two-element compound selected from a group consisting of GaN, GaP, GaAs, GaSb, AlN, AlP, AlAs, AlSb, InN, InP, InAs, InSb, and/or a (e.g., any suitable) combination(s) thereof; a three-element compound selected from a group consisting of GaNP, GaNAs, GaNSb, GaPAs, GaPSb, AlNP, AlNAs, AlNSb, AlPAs, AlPSb, InNP, InAlP, InNAs, InNSb, InPAs, InPSb, GaAlNP, and/or a (e.g., any suitable) combination(s) thereof; and a four-element compound selected from a group consisting of) GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or a (e.g., any suitable) combination(s) thereof. The Group III-V semiconductor compound may further include a Group II metal (for example, InZnP).

The Group IV-VI compound may be selected from a group consisting of: a two-element compound selected from a group consisting of SnS, SnSe, SnTe, PbS, PbSe, PbTe, and/or a (e.g., any suitable) combination(s) thereof; a three-element compound selected from a group consisting of SnSeS, SnSeTe, SnSTe, PbSeS, PbSeTe, PbSTe, SnPbS, SnPbSe, SnPbTe, and/or a (e.g., any suitable) combination thereof; and a four-element compound selected from a group consisting of SnPbSSe, SnPbSeTe, SnPbSTe, and/or a (e.g., any suitable) combination(s) thereof. The Group IV element may be selected from a group consisting of Si, Ge, and/or a (e.g., any suitable) combination(s) thereof. The Group IV compound may include a two-element compound selected from a group consisting of SiC, SiGe, and/or a (e.g., any suitable) combination(s) thereof.

The second quantum-dot layer 520 may convert the blue light Lb, which is incident to the second quantum-dot layer 520, into the green light Lg. The second quantum-dot layer 520 may include a second photosensitive polymer 521, and second quantum dots 522 and second scattering particles 523 dispersed in the second photosensitive polymer 521.

The second quantum dots 522 may be excited by the blue light Lb to emit the green light Lg having a wavelength greater than a wavelength of the blue light Lb. The second photosensitive polymer 521 may include an organic material having light transmissivity.

The second scattering particles 523 may scatter the blue light Lb that has not been absorbed by the second quantum dots 522 to excite more of the second quantum dots 522, and thus the second scattering particles 523 may increase the efficiency of color conversion. The second scattering particles 523 may include, for example, titanium dioxide (TiO₂) particles and/or metal particles. The second quantum dots 522 may be selected from among the Group II-VI compound, the Group III-V compound, the Group IV-VI compound, the Group IV element, the Group IV compound, and/or a (e.g., any suitable) combination(s) thereof.

In one or more embodiments, the first quantum dots 512 and the second quantum dots 522 may include the same material. In such embodiments, the size of the first quantum dots 512 may be greater than the size of the second quantum dots 522.

The light transmission layer 530 may be to transmit the blue light Lb, which is incident to the light transmission layer 530, without conversion. The light transmission layer 530 may include a third photosensitive polymer 531 in which third scattering particles 533 are dispersed. The third photosensitive polymer 531 may include, for example, an organic material having light transmissivity such as silicon resin and/or epoxy resin, and may include the same material as the materials of the first photosensitive polymer 511 and/or the second photosensitive polymer 521. The third scattering particles 533 may scatter and emit the blue light Lb, and may include the same material as the materials of the first scattering particles 513 and/or the second scattering particles 523.

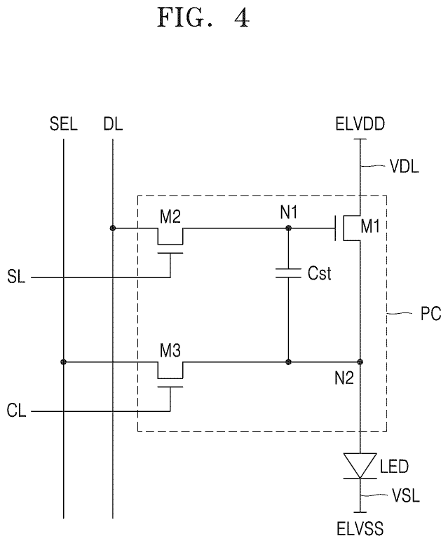

FIG. 4 is an equivalent circuit diagram of a light-emitting element included in a display device and a sub-pixel circuit electrically connected to the light-emitting element, according to one or more embodiments of the present disclosure.

Referring to FIG. 4, a sub-pixel electrode (for example, an anode) of the light-emitting element LED is electrically connected to the sub-pixel circuit PC, and an opposite electrode (for example, a cathode) of the light-emitting element LED may be connected to a common voltage line VSL configured to provide a common power voltage ELVSS. The light-emitting element LED may be to emit light at a luminance corresponding to an amount of current provided from the sub-pixel circuit PC.

The light-emitting element LED shown in FIG. 4 may correspond to each of the first light-emitting element LED1, the second light-emitting element LED2, and the third light-emitting element LED3 shown in FIG. 2, and the sub-pixel circuit PC shown in FIG. 4 may correspond to each of the first sub-pixel circuit PC1, the second sub-pixel circuit PC2, and the third sub-pixel circuit PC3 shown in FIG. 2.

The sub-pixel circuit PC may control, in response to a data signal, an amount of current flowing from the driving power voltage ELVDD to the common power voltage ELVSS via the light-emitting element LED. The sub-pixel circuit PC may include a first transistor M1, a second transistor M2, a third transistor M3, and a storage capacitor Cst.

Each of the first transistor M1, the second transistor M2, and the third transistor M3 may include an oxide semiconductor thin film transistor including a semiconductor layer including an oxide semiconductor, or may include a silicon semiconductor thin film transistor including a semiconductor layer including polysilicon. The transistor may include a first electrode and a second electrode. According to the type (kind) of the transistor, the first electrode may include (e.g., be) one of a source electrode or a drain electrode, and the second electrode may include the other one of the source electrode or the drain electrode. For example, depending on the type (kind) of transistor, the first electrode may be either a source electrode or a drain electrode, and the second electrode will be the other one.

The first transistor M1 may include a driving transistor. A first electrode of the first transistor M1 is electrically connected to the driving power line VDL configured to provide the driving power voltage ELVDD, and the second electrode may be electrically connected to a sub-pixel electrode of the light-emitting element LED. A gate electrode of the first transistor M1 may be electrically connected to the first node N1. The first transistor M1 may control, in response to a voltage of the first node N1, an amount of current flowing from the driving power voltage ELVDD to the light-emitting element LED.

The second transistor M2 may include a switching transistor. A first electrode of the second transistor M2 may be electrically connected to a data line DL, and the second electrode may be electrically connected to the first node N1. A gate electrode of the second transistor M2 may be electrically connected to a scan line SL. The second transistor M2 may be turned on if (e.g., when) a scan signal is provided to the scan line SL to electrically connect the data line DL to the first node N1.

The third transistor M3 may include an initialization transistor and/or a sensing transistor. A first electrode of the third transistor M3 may be electrically connected to the second node N2, and a second electrode may be connected to a sensing line SEL. A gate electrode of the third transistor M3 may be electrically connected to a control line CL.

The third transistor M3 may be turned on if (e.g., when) a control signal is provided to the control line CL, to electrically connect the sensing line SEL to the second node N2. In one or more embodiments, the third transistor M3 may be turned on in response to a signal received through the control line CL, and may be to transmit an initialization voltage from the sensing line SEL to the light-emitting element LED to initialize a sub-pixel electrode. In one or more embodiments, the third transistor M3 may be turned on if (e.g., when) the control signal is provided to the control line CL to sense characteristic information of the light-emitting element LED. The third transistor M3 may have both (e.g., simultaneously) a function as the initialization transistor and a function as the sensing transistor described above or may have one of these functions. In one or more embodiments, if (e.g., when) the third transistor M3 has the function as the initialization transistor, the sensing line SEL may be referred to as an initialization voltage line. An initialization operation and a sensing operation of the third transistor M3 may be individually performed or may be concurrently (e.g., simultaneously) performed.

The storage capacitor Cst may be connected between the first node N1 and the second node N2. For example, a first capacitor electrode of the storage capacitor Cst may be electrically connected to the gate electrode of the first transistor M1, and a second capacitor of the storage capacitor Cst may be electrically connected to the sub-pixel electrode of the light-emitting element LED.

Although FIG. 4 illustrates that each of the first transistor M1, the second transistor M2, and the third transistor M3 includes an N-type (kind) metal oxide semiconductor (NMOS), in one or more embodiments, at least one of the first transistor M1, the second transistor M2, and the third transistor M3 may include a P-type (kind) metal oxide semiconductor (PMOS).

Although three transistors are shown in FIG. 4, in one or more embodiments, the sub-pixel circuit PC may include four or more transistors.

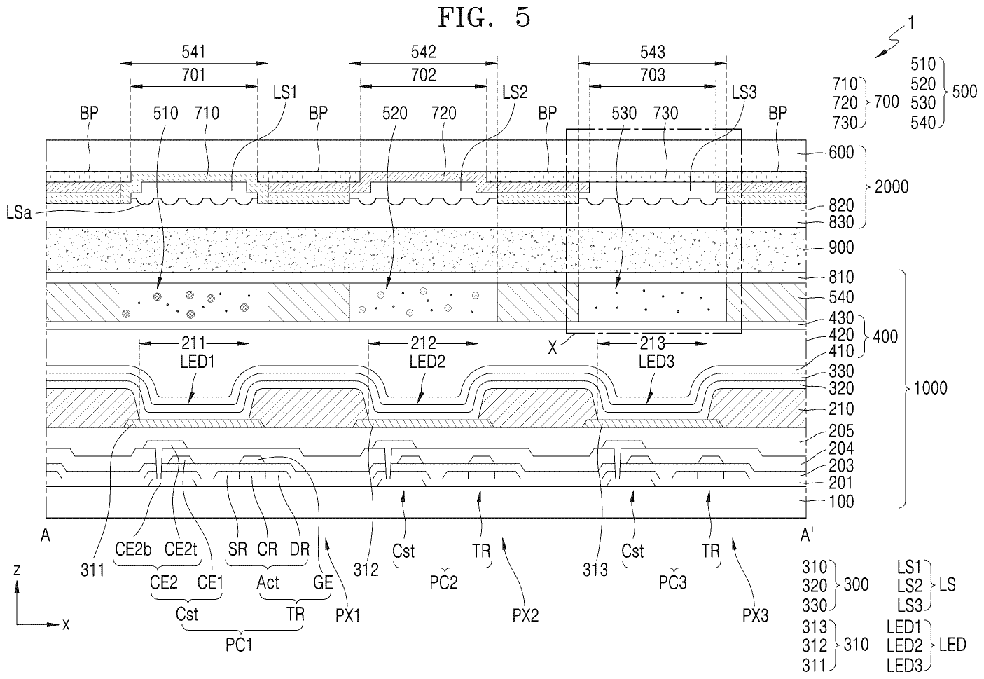

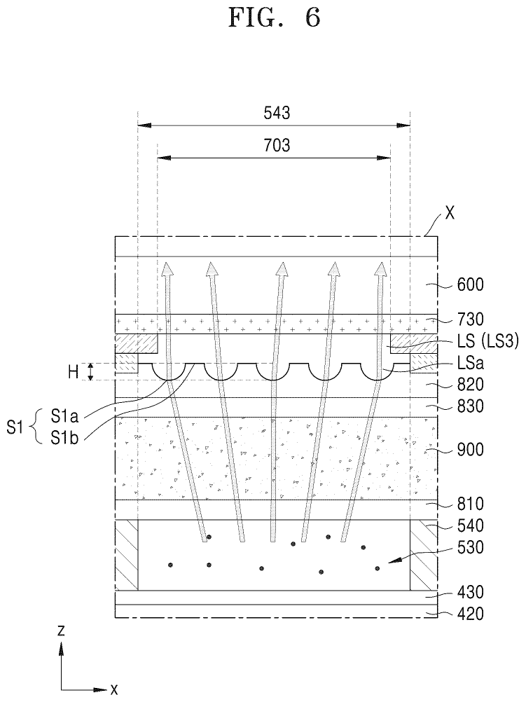

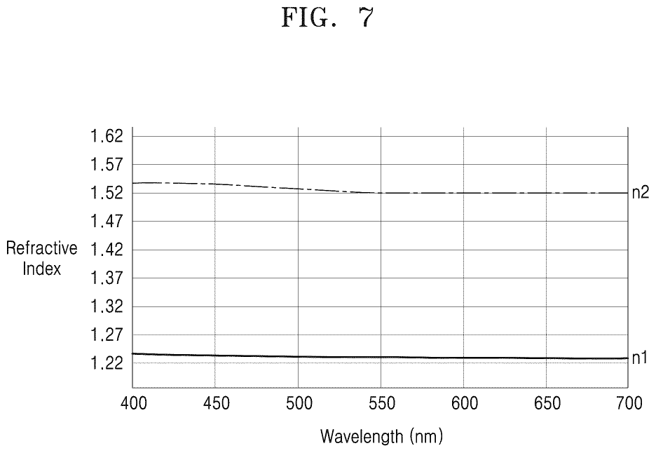

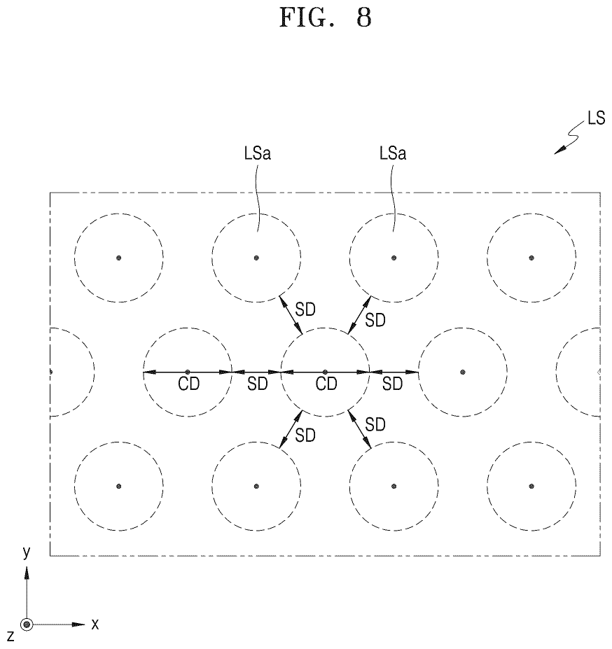

FIG. 5 is a schematic cross-sectional view of the display device 1 taken along the line A-A′ of FIG. 1, according to one or more embodiments of the present disclosure, and FIG. 6 is an enlarged cross-sectional view schematically illustrating the region X of FIG. 5 in the display device 1, according to one or more embodiments of the present disclosure. While FIG. 6 is an enlarged view of a portion of the area above the third light-emitting element LED3, the areas above the remaining light-emitting elements LED1, LED2 may have the same or similar configurations. In one or more embodiments, FIG. 7 is a graph showing refractive indices of a lens layer and a low-refractive layer included in the display device 1 according to one or more embodiments of the present disclosure, and FIG. 8 is a plan view schematically showing a lens layer included in the display device 1 according to one or more embodiments of the present disclosure.

Referring to FIG. 5, the light-emitting panel 1000 may include the first substrate 100, the circuit layer 200, the light-emitting element layer 300, the encapsulation layer 400, the functional layer 500, and the first passivation layer 810. The circuit layer 200 may include first to third sub-pixel circuits PC1, PC2, and PC3 arranged on the first substrate 100.

The first substrate 100 may include a glass substrate having SiO₂ as a main component. The glass substrate may include, for example, a glass substrate having a thickness of about 500 μm or may include an ultra-thin glass substrate having a thickness of about 30 μm. In one or more embodiments, the first substrate 100 may include a polymer resin. The first substrate 100 including the polymer resin may be flexible, foldable, rollable, or bendable. In one or more embodiments, the first substrate 100 may have a multi-layer structure including a layer including a polymer resin and an inorganic layer.

The first to third sub-pixel circuits PC1, PC2, and PC3 each include the first transistor M1 (see, e.g., FIG. 4), the second transistor M2 (see, e.g., FIG. 4), the third transistor M3 (see, e.g., FIG. 4), and the storage capacitor Cst (see, e.g., FIG. 4) as described above with reference to FIG. 4. By way of example, FIG. 5 illustrates a storage capacitor Cst and a transistor TR corresponding to one of the first transistor M1 (see, e.g., FIG. 4), the second transistor M2 (see, e.g., FIG. 4), or the third transistor M3 (see, e.g., FIG. 4). The remaining transistors of the first transistor M1 (see, e.g., FIG. 4), the second transistor M2 (see, e.g., FIG. 4), or the third transistor M3 may have the same or similar configuration to that shown in FIG. 5.

In one or more embodiments, the storage capacitor Cst may include a first capacitor electrode CE1 and a second capacitor electrode CE2, and the second capacitor electrode CE2 may include a first sub-capacitor electrode CE2b and a second sub-capacitor electrode CE2t, respectively arranged above and under the first capacitor electrode CE1 in a thickness direction (e.g., the x-axis direction).

The first sub-capacitor electrode CE2b may be arranged on the first substrate 100. For example, the first sub-capacitor electrode CE2b may directly contact an upper surface of the first substrate 100. The first sub-capacitor electrode CE2b may include a conductive material, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu).

The buffer layer 201 may be arranged above the first sub-capacitor electrode CE2b, and may include an inorganic insulating material. The buffer layer 201 may include an inorganic insulating material such as silicon nitride, silicon oxide, and/or silicon oxynitride, and may include a single-layer structure or multi-layer structure including the aforementioned materials.

A semiconductor layer Act may be arranged on the buffer layer 201. The semiconductor layer Act may include an oxide semiconductor material such as IGZO, amorphous silicon, polycrystalline silicon, and/or an organic semiconductor material.

A gate insulating layer 203 may be arranged on the semiconductor layer Act. The gate insulating layer 203 may include an inorganic insulating material such as silicon nitride and/or silicon oxynitride, and may include a single-layer structure or a multi-layer structure including the aforementioned materials.

The gate electrode GE may be arranged on the gate insulating layer 203 and may overlap a portion of the semiconductor layer Act. The gate electrode GE may overlap a channel region CR of the semiconductor layer Act, and the semiconductor layer Act may include the channel region CR, and a source region SR and a drain region DR respectively arranged at two sides of the channel region CR (e.g., at opposite sides of the channel region CR in the x-axis and/or y-axis direction).

The first capacitor electrode CE1 may be arranged on the same layer and may include the same material as the gate electrode GE. The first capacitor electrode CE1 and the gate electrode GE may be formed by the same process. The first capacitor electrode CE1 and the gate electrode GE may each include a conductive metal such as Al, Pt, Pd, Ag, Mg, Au, Ni, Nd, Ir, Cr, Ni, Ca, Mo, Ti, W, and/or Cu. According to one or more embodiments, the first capacitor electrode CE1 and the gate electrode GE may each have a layer structure including Mo/Al/Mo. In one or more embodiments, the first capacitor electrode CE1 and the gate electrode GE may include a TiNx layer, an Al layer, and/or a Ti layer.

An interlayer insulating layer 204 may be arranged on the first capacitor electrode CE1 and the gate electrode GE. The interlayer insulating layer 204 may include an inorganic insulating material such as silicon nitride, silicon oxide, and/or silicon oxynitride, and may include a single-layer structure or a multi-layer structure including the aforementioned materials.

The second sub-capacitor electrode CE2t may be arranged on the interlayer insulating layer 204. The second sub-capacitor electrode CE2t may be electrically connected to the first sub-capacitor electrode CE2b via a contact hole in the insulating layer(s) between the first sub-capacitor electrode CE2b and the second sub-capacitor electrode CE2t. For example, the second sub-capacitor electrode CE2t may contact the first sub-capacitor electrode CE2b via a contact hole through the buffer layer 201, the gate insulating layer 203, and the interlayer insulating layer 204. The second sub-capacitor electrode CE2t may include, for example, a Ti layer, an Al layer, and/or a Cu layer. In one or more embodiments, the second sub-capacitor electrode CE2t may have a layered structure of Ti/Al/Ti.

The via insulating layer 205 may be arranged on the first to third sub-pixel circuits PC1, PC2, and PC3. The via insulating layer 205 may include an inorganic insulating material and/or an organic insulating material. For example, the via insulating layer 205 may include an organic insulating material such as acryl, benzocyclobutene (BCB), polyimide, or hexamethyldisiloxane (HMDSO). The via insulating layer 205 may be provided as a single layer or a multi-layer.

Each of the first sub-pixel circuit PC1, the second sub-pixel circuit PC2, and the third sub-pixel circuit P3 arranged on the first substrate 100 may include the transistor TR and the storage capacitor Cst having the structures described above, and may be electrically connected to a sub-pixel electrode 310 of the corresponding light-emitting element LED1, LED2, and LED3, respectively.

The sub-pixel electrode 310 may include a light-transmitting conductive oxide such as indium tin oxide (ITO), indium zinc oxide (IZO), zinc oxide (ZnO), indium oxide (In2O3), indium gallium oxide (IGO), or aluminum zinc oxide (AZO). The sub-pixel electrode 310 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. For example, the sub-pixel electrode 310 may have a three-layer structure of ITO/Ag/ITO. In one or more embodiments, the sub-pixel electrode 310 may include a first sub-pixel electrode 311, a second sub-pixel electrode 312, and a third sub-pixel electrode 313.

The first light-emitting element LED1 including the first sub-pixel electrode 311, an opposite electrode 330, and an intermediate layer 320 located therebetween, which includes an emission layer, may be positioned in the first sub-pixel PX1. The second light-emitting element LED2 including the second sub-pixel electrode 312, the opposite electrode 330, and the intermediate layer 320 located therebetween, which includes the emission layer, may be positioned in the second sub-pixel PX2. In addition, the third light-emitting element LED3 including the third sub-pixel electrode 313, the opposite electrode 330, and the intermediate layer 320, which includes the emission layer, may be positioned in the third sub-pixel PX3.

The intermediate layer 320 may include a polymer or low-molecular weight organic material that emits light of a certain color. The intermediate layer 320 may further include metal-containing compounds such as organometallic compounds, and/or inorganic materials such as quantum dots, as well as one or more suitable organic materials.

In one or more embodiments, the intermediate layer 320 may include the emission layer and a first functional layer and a second functional layer arranged below and above the emission layer, respectively. The first functional layer may include, for example, a hole transport layer (HTL) or a hole transport layer and a hole injection layer (HIL). The second functional layer is an optional component arranged on the emission layer. The second functional layer may include an electron transport layer (ETL) and/or an electron injection layer (EIL).

The intermediate layer 320 may be arranged not only on the first sub-pixel electrode 311 of the first sub-pixel PX1, but also on the second sub-pixel electrode 312 of the second sub-pixel PX2 and the third sub-pixel electrode 313 of the third sub-pixel PX3. The intermediate layer 320 may have a unified shape (e.g., may be a single, continuous layer) extending over (e.g., extending over an entirety of) the first sub-pixel electrode 311, the second sub-pixel electrode 312, and the third sub-pixel electrode 313. If desired and/or necessary, the intermediate layer 320 may be patterned and positioned (e.g., separately positioned) on the first sub-pixel electrode 311, the second sub-pixel electrode 312, and/or the third sub-pixel electrode 313. The intermediate layer 320 may also include, in addition to the emission layer, a hole injection layer, a hole transport layer, and/or an electron transport layer, as desired and/or needed. The layers included in the intermediate layer 320 may also have a unified shape (e.g., may be a single, continuous layer) extending over (e.g., extending over an entirety of) the first sub-pixel electrode 311, the second sub-pixel electrode 312, and the third sub-pixel electrode 313. Some of the layers included in the intermediate layer 320 may be patterned and positioned (e.g., separately positioned) on the first sub-pixel electrode 311, the second sub-pixel electrode 312, and/or the third sub-pixel electrode 313 as desired and/or needed.

In one or more embodiments, the intermediate layer 320 may include a single emission layer. The first to third light-emitting elements LED1, LED2, and LED3 may be to emit blue light. However, the present disclosure is not necessarily limited thereto, and in one or more embodiments, the intermediate layer 320 may have a laminated structure including at least two emission units that emit light of different wavelength bands.

The first to third light-emitting elements LED1, LED2, and LED3 may be to emit light within a first wavelength band. For example, the first to third light-emitting elements LED1, LED2, and LED3 may be to emit light within the first wavelength band toward the first quantum-dot layer 510, the second quantum-dot layer 520, and the light transmission layer 530. For example, the first to third light-emitting elements LED1, LED2, and LED3 may be to emit blue light. In one or more embodiments, the first to third light-emitting elements LED1, LED2, and LED3 may be to emit light in a wavelength band with a center wavelength in a range of about 450 nm to about 495 nm.

The opposite electrode 330 may be arranged on the intermediate layer 320. The opposite electrode 330 may include a metal, an alloy, an electrically conductive compound, or a (e.g., any suitable) combination thereof having a low work function. For example, the opposite electrode 330 may include lithium (Li), silver (Ag), magnesium (Mg), aluminum (Al), aluminum-lithium (Al-Li), calcium (Ca), magnesium-indium (Mg—In), magnesium-silver (Mg—Ag), ytterbium (Yb), silver-ytterbium (Ag—Yb), ITO, IZO, or a (e.g., any suitable) combination thereof. The opposite electrode 330 may be a transmissive electrode, a semi-transmissive electrode, or a reflective electrode.

The opposite electrode 330 may have a unified shape (e.g., may be a single, continuous layer) extending over (e.g., extending over an entirety of) the first to third sub-pixel electrodes 311, 312, and 313.

A first bank layer 210 may be arranged on the via insulating layer 205. The first bank layer 210 may have sub-pixel openings corresponding to the sub-pixels PX1, PX2, and PX3. The first bank layer 210 may cover the edges of each of the first sub-pixel electrode 311, the second sub-pixel electrode 312, and the third sub-pixel electrode 313, and may have a first sub-pixel opening 211 exposing the central portion of the first sub-pixel electrode 311, a second sub-pixel opening 212 exposing the central portion of the second sub-pixel electrode 312, and a third sub-pixel opening 213 exposing the central portion of the third sub-pixel electrode 313. A portion of the first bank layer 210 excluding the first to third sub-pixel openings 211, 212, and 213 may be referred to as a body portion having a certain thickness. The first bank layer 210 may prevent or reduce the likelihood of an arc and/or the like from occurring at edges of the first sub-pixel electrode 311, the second sub-pixel electrode 312, and/or the third sub-pixel electrode 313 by increasing the electrical distance between the edges of each of the first sub-pixel electrode 311, the second sub-pixel electrode 312, and the third sub-pixel electrode 313.

The first to third sub-pixel openings 211, 212, and 213 of the first bank layer 210 may define emission areas of the first to third light-emitting elements LED1, LED2, and LED3, respectively. For example, the first sub-pixel opening 211 of the first bank layer 210 corresponding to the first light-emitting element LED1 may define the first emission area, the second sub-pixel opening 212 of the first bank layer 210 corresponding to the second light-emitting element LED2 may define the second emission area, and the third sub-pixel opening 213 of the first bank layer 210 corresponding to the third light-emitting element LED3 may define the third emission area. The first bank layer 210 may include an organic material such as polyimide and/or hexamethyldisiloxane (HMDSO).

The first to third light-emitting elements LED1, LED2, and LED3, which are organic light-emitting diodes, may easily deteriorate due to moisture or oxygen. Accordingly, an encapsulation layer 400 may be arranged on the first to third light-emitting elements LED1, LED2, and LED3. The encapsulation layer 400 may be arranged to cover the first bank layer 210 and the first to third light-emitting elements LED1, LED2, and LED3. The encapsulation layer 400 may protect the first to third light-emitting elements LED1, LED2, and LED3 from moisture, oxygen, and/or other external factors. The encapsulation layer 400 may include at least one inorganic encapsulation layer and at least one organic encapsulation layer. For example, the encapsulation layer 400 may include a first inorganic encapsulation layer 410 and a second inorganic encapsulation layer 430, and an organic encapsulation layer 420 therebetween. In one or more embodiments, the encapsulation layer 400 may include a first inorganic encapsulation layer 410, a second inorganic encapsulation layer 430, and an organic encapsulation layer 420 between the first inorganic encapsulation layer 410 and the second inorganic encapsulation layer 430.

Each of the first inorganic encapsulation layer 410 and the second inorganic encapsulation layer 430 may include one or more inorganic insulating materials. The inorganic insulating material may include one or more inorganic insulating materials, such as silicon oxide, silicon nitride, silicon oxynitride, aluminum oxide, titanium oxide, tantalum oxide, hafnium oxide and/or zinc oxide. The organic encapsulation layer 420 may include a polymer-based material. The polymer-based material may include an acrylic resin, an epoxy-based resin, polyimide, polyethylene, and/or the like. For example, the organic encapsulation layer 420 may include an acrylic resin, for example, polymethylmethacrylate, polyacrylate, and/or the like. The organic encapsulation layer 420 may be formed by curing a monomer or coating a polymer.

The first inorganic encapsulation layer 410 may be formed by a chemical vapor deposition (CVD) method and may have an approximately (e.g., substantially) uniform thickness, which may result in an uneven upper surface. However, an upper surface of the organic encapsulation layer 420 may be approximately flat (as shown, for example, in FIG. 5), and accordingly, an upper surface of the second inorganic encapsulation layer 430 on the organic encapsulation layer 420 may also be approximately flat.

A second bank layer 540 may be arranged on the encapsulation layer 400. A first bank opening 541, a second bank opening 542, and a third bank opening 543 may be defined in the second bank layer 540. A portion of the second bank layer 540 excluding the first bank openings 541, 542, and 543 may be referred to as a body portion having a certain thickness. The first bank opening 541 may correspond (e.g., substantially correspond) to the first sub-pixel opening 211 exposing the first sub-pixel electrode 311 of the first bank layer 210, the second bank opening 542 may correspond (e.g., substantially correspond) to the second sub-pixel opening 212 exposing the second sub-pixel electrode 312 of the first bank layer 210, and the third bank opening 543 may correspond (e.g., substantially correspond) to the third sub-pixel opening 213 exposing the third sub-pixel electrode 313 of the first bank layer 210.

The second bank layer 540 may include one or more suitable materials such as an organic material or an inorganic material. The second bank layer 540 may include, for example, an inorganic material such as silicon oxide, silicon nitride, and/or silicon oxynitride, or an organic material such as acrylic, benzocyclobutene (BCB), or hexamethyldisiloxane (HMDSO). In some embodiments, the second bank layer 540 may include a light-blocking material to function as a light-blocking layer. The light-blocking material may include, for example, at least one of a black pigment, a black dye, black particles and/or metal particles.

The second bank layer 540 may prevent or reduce the likelihood of light converted and scattered in the first quantum-dot layer 510, the second quantum-dot layer 520, and the light transmission layer 530 from proceeding to other areas. In addition, the second bank layer 540, together with the color filter layer 700 described in more detail later, may improve the contrast of the display device 1 by preventing or reducing the reflection of external light.

The first quantum-dot layer 510 may be located in the first bank opening 541 of the second bank layer 540. The second quantum-dot layer 520 may be located in the second bank opening 542 of the second bank layer 540. The light transmission layer 530 may be located in the third bank opening 543. Materials included in the first quantum-dot layer 510, the second quantum-dot layer 520, and the light transmission layer 530 may each independently be the same as described above with reference to FIG. 3. Each of the first quantum-dot layer 510, the second quantum-dot layer 520, and the light transmission layer 530 may be formed using an inkjet method.

The first quantum-dot layer 510 may convert light within the first wavelength band emitted from the first light-emitting element LED1 into light within a second wavelength band. For example, the first quantum-dot layer 510 may convert blue light into red light. The second quantum-dot layer 520 may convert light within the first wavelength band emitted from the second light-emitting element LED2 into light within a third wavelength band. For example, the second quantum-dot layer 520 may convert blue light into green light. In one or more embodiments, the wavelength bands of the target wavelengths converted by the first quantum-dot layer 510 and the second quantum-dot layer 520, as well as the wavelength bands of the converted wavelengths, may be modified differently (e.g., may provide light of different color wavelengths, different wavelength bands, and/or the like).

In one or more embodiments, the first quantum-dot layer 510, the second quantum-dot layer 520, the light transmission layer 530, and the second bank layer 540 included in the functional layer 500 may be each arranged to directly contact the second inorganic encapsulation layer 430 of the encapsulation layer 400.

In one or more embodiments, a first passivation layer 810 may be arranged on the functional layer 500. The first quantum-dot layer 510, the second quantum-dot layer 520, the light transmission layer 530, and the second bank layer 540 may each include an organic material and may be covered by the first passivation layer 810 to prevent or reduce moisture ingress and/or other issues related to organic materials. The first passivation layer 810 includes, for example, an inorganic material such as silicon oxide, silicon nitride, and/or silicon oxynitride, and may be formed by a chemical vapor deposition (CVD) method.

In one or more embodiments, the color filter panel 2000 may include the second substrate 600, the color filter layer 700, a lens layer LS, a low-refractive layer 820, and a second passivation layer 830. The second substrate 600 may be arranged to face the first substrate 100 with the light-emitting elements LED interposed therebetween. The second substrate 600 may be arranged on the first to third light-emitting elements LED1, LED2, and LED3.

The second substrate 600 may include a glass substrate having SiO₂ as a main component. The glass substrate may include, for example, a glass substrate having a thickness of about 500 μm, or may include an ultra-thin glass substrate having a thickness of about 30 μm. In one or more embodiments, the second substrate 600 may include a polymer resin. The second substrate 600 including the polymer resin may have flexible, foldable, rollable, and/or bendable characteristics. In one or more embodiments, the second substrate 600 may have a multilayer structure including a layer including a polymer resin and an inorganic layer.

The color filter layer 700 may be arranged on the surface of the second substrate 600 facing (e.g., opposite to) the first substrate 100. The color filter layer 700 may be arranged between the second substrate 600 and the second bank layer 540. In one or more embodiments, the color filter layer 700 may be arranged to face the functional layer 500 with the filler 900 therebetween.

The color filter layer 700 may include a first color filter 710, a second color filter 720, and a third color filter 730. When viewed in a direction normal (e.g., perpendicular) to the first substrate 100 (e.g., the z-axis direction, also referred to as a −z direction, as it is the direction opposite to the arrow illustrating the z-axis in the drawings), the first color filter 710 may be located in the first sub-pixel PX1 to overlap the first light-emitting element LED1, the second color filter 720 may be located in the second sub-pixel PX2 to overlap the second light-emitting element LED2, and the third color filter 730 may be located in the third sub-pixel PX3 to overlap the third light-emitting element LED3.

In one or more embodiments, the first color filter 710 may pass (e.g., may be to transmit) the red light emitted from the first quantum-dot layer 510. The second color filter 720 may pass (e.g., may be to transmit) the green light emitted from the second quantum-dot layer 520. The third color filter 730 may be to transmit the blue light from among the light emitted from the third light-emitting element LED3.

The color filter layer 700 may reduce the reflection of external light of the display device 1. For example, if (e.g., when) external light reaches the first color filter 710, only light of a set or predetermined wavelength may pass through the first color filter 710, and light of other wavelengths may be absorbed by the first color filter 710. Some of the light passing through the first color filter 710 may be reflected by the underlying opposite electrode 330 and/or the first sub-pixel electrode 311 and subsequently emitted back to the outside. Therefore, because only a portion of the external light incident on the location of the first sub-pixel PX1 is reflected outside, reflection of the external light may be reduced.

In one or more embodiments, the color filter layer 700 may improve the color purity of the display device 1. Color purities of lights converted and transmitted by the functional layer 500 may be improved by the first to third color filters 710, 720, and 730.

As shown in FIG. 5, the third color filter 730 may have a second filter opening 702 corresponding to the second light-emitting element LED2. The second color filter 720 may fill at least the second filter opening 702 of the third color filter 730.

Also, the second color filter 720 may have a third filter opening 703 corresponding to the third light-emitting element LED3. The third color filter 730 may be exposed by the third filter opening 703 of the second color filter 720.

The third color filter 730 may have a first filter opening 701 corresponding to the first light-emitting element LED1. The first color filter 710 may fill at least the first filter opening 701 of the third color filter 730.

The first color filter 710, the second color filter 720, and the third color filter 730 may overlap each other. At least two selected from among the first color filter 710, the second color filter 720, and the third color filter 730 may overlap each other to define a light-blocking portion. In one or more embodiments, the first color filter 710, the second color filter 720, and the third color filter 730 may overlap to define a light-blocking portion BP. In one or more embodiments, the light-blocking portion BP may be formed by overlapping at least two color filters selected from among the first color filter 710, the second color filter 720, and the third color filter 730. The light-blocking portion BP may serve as a black matrix. The color filter layer 700 may prevent or reduce color mixing without the need to use a separate light-blocking member. The light-blocking portion BP may overlap the body portion of the second bank layer 540.

FIG. 5 describes one or more embodiments in which the third color filter 730, the second color filter 720, and the first color filter 710 are sequentially arranged on the second substrate 600, but the stacking order of the first color filter 710, the second color filter 720, and the third color filter 730 may be changed.

Referring to FIG. 5, the lens layer LS may be arranged on the surface of the color filter layer 700 facing (e.g., opposite to) the functional layer 500. The lens layer LS may correspond to at least one light-emitting element LED. The lens layer LS may include lens layers LS corresponding to each of the light-emitting elements LED. The lens layer LS may include a first lens layer LS1 corresponding to the first light-emitting element LED1, a second lens layer LS2 corresponding to the second light-emitting element LED2, and a third lens layer LS3 corresponding to the third light-emitting element LED3. However, the present disclosure is not necessarily limited thereto. In one or more embodiments, at least one of the first lens layer LS1, the second lens layer LS2, and the third lens layer LS3 may not be provided. For example, the lens layer LS may include only a first lens layer LS1 corresponding to the first light-emitting element LED1 and a second lens layer LS2 corresponding to the second light-emitting element LED2.

In one or more embodiments, the first lens layer LS1, the second lens layer LS2, and the third lens layer LS3 may be spaced and/or apart (e.g., spaced apart or separated) from each other. The first lens layer LS1, the second lens layer LS2, and the third lens layer LS3 may not overlap at least a portion of the light-blocking portion BP of the color filter layer 700. In one or more embodiments, the first lens layer LS1, the second lens layer LS2, and the third lens layer LS3 may not overlap the light-blocking portion BP of the color filter layer 700.

In one or more embodiments, the first lens layer LS1 may correspond to the first filter opening 701 of the third color filter 730, the second lens layer LS2 may correspond to the second filter opening 702 of the third color filter 730, and the third lens layer LS3 may correspond to the third filter opening 703 of the second color filter 720.

The first lens layer LS1 may be in direct contact with the first color filter 710 filling the first filter opening 701 of the third color filter 730. The second lens layer LS2 may be in direct contact with the second color filter 720 filling the second filter opening 702 of the third color filter 730. The third lens layer LS3 may be in direct contact with the third color filter 730 exposed by the third filter opening 703 of the second color filter 720.

The lens layer LS may include a plurality of lenses LSa. FIG. 5 shows that each of the first lens layer LS1, the second lens layer LS2, and the third lens layer LS3 includes five lenses LSa, but the present disclosure is not necessarily limited thereto. In one or more embodiments, each of the first lens layer LS1, the second lens layer LS2, and the third lens layer LS3 may include two or more but less than five lenses LSa, or six or more lenses LSa.

Each of the plurality of lenses LSa of the lens layer LS may have a convex shape in a direction opposite to the direction of the light emitted from the light-emitting element layer 300 and passing through the functional layer 500. For example, each of the plurality of lenses LSa may have a convex shape in a −z direction. The plurality of lenses LSa may be portions protruding from the second substrate 600 toward the functional layer 500.

In one or more embodiments, the plurality of lenses LSa may be arranged to cover the entirety of the region corresponding to the light-emitting elements LED. However, the present disclosure is not necessarily limited thereto. In one or more embodiments, depending on desired or required light characteristics, the plurality of lenses LSa may be arranged only at positions corresponding to centers of the light-emitting elements LED and not at positions corresponding to peripheries of the light-emitting elements LED. In one or more embodiments, the plurality of lenses LSa may be arranged only at the positions corresponding to the peripheries of the light-emitting elements LED and not at the positions corresponding to the centers of the light-emitting elements LED.

In one or more embodiments, the plurality of lenses LSa may be arranged at regular intervals from each other. However, the present disclosure is not necessarily limited thereto. In one or more embodiments, depending on the desired or required optical characteristics, at least some of the plurality of lenses LSa may be arranged at different intervals.

The low-refractive layer 820 may be arranged on a surface of the color filter layer 700 and the lens layer LS facing (e.g., opposite to) the functional layer 500. The low-refractive layer 820 may be arranged to directly contact the lens layer LS. In one or more embodiments, the low-refractive layer 820 may be arranged to directly contact a portion of the color filter layer 700. The low-refractive layer 820 may be in direct contact with the first lens layer LS1, the second lens layer LS2, and the third lens layer LS3. The low-refractive layer 820 may be continuously arranged over the first lens layer LS1, the second lens layer LS2, and the third lens layer LS3. The low-refractive layer 820 may flatten (e.g., may provide a substantially flat surface on) the color filter layer 700 and the lens layer LS.

Referring to FIG. 6, a surface S1 of the lens layer LS in contact with the low-refractive layer 820 may include convex surfaces S1a of each of the plurality of lenses LSa and flat surfaces S1b between the convex surfaces S1a. In one or more embodiments, the convex surfaces S1a of each of the plurality of lenses LSa may have same curvature.

In one or more embodiments, the maximum vertical distance H (e.g., in a z-axis direction) from the flat surface S1b of the lens layer LS to the convex surface S1a of one lens LSa among the plurality of lenses LSa may be the same as the maximum vertical distance H from the flat surface S1b of the lens layer LS to the convex surface S1a of another lens LSa among the plurality of lenses LSa. However, the present disclosure is not necessarily limited thereto. In one or more embodiments, the convex surface S1a of each of at least some lenses LSa among the plurality of lenses LSa may have a different curvature than the convex surface S1a of each of the other lenses LSa among the plurality of lenses LSa. Thus, the maximum vertical distance from the flat surface S1b of the lens layer LS to the convex surface S1a of each of at least some lenses LSa among the plurality of the lenses LSa may be different from the maximum vertical distance from the flat surface S1b of the lens layer LS to the convex surface S1a of each of the other lenses LSa among the plurality of lenses LSa.

The lens layer LS may include a transparent organic material. In one or more embodiments, a refractive index of the lens layer LS may be about in a range of 1.50 to about 1.75. In one or more embodiments, the refractive index of the lens layer LS may be in a range of about 1.60 to about 1.70.

The low-refractive layer 820 may include an organic material. The low-refractive layer 820 may be a layer having a low refractive index by dispersing porous particles such as hollow silica in an organic material. In one or more embodiments, the low-refractive layer 820 may include an organic material having a low refractive index. In one or more embodiments, a refractive index of the low-refractive layer 820 may in a range of about 1.0 to about 1.3. In one or more embodiments, the refractive index of the low-refractive layer 820 may be in a range of about 1.0 to about 1.25. In one or more embodiments, the refractive index of the low-refractive layer 820 may be in a range of about 1.2 to about 1.25.

The refractive index of the low-refractive layer 820 may be less than the refractive index of the lens layer LS. In one or more embodiments, a difference between the refractive index of the lens layer LS and the refractive index of the low-refractive layer 820 may be in a range of about 0.2 to about 0.75. In one or more embodiments, the difference between the refractive index of the lens layer LS and the refractive index of the low-refractive layer 820 may be in a range of about 0.2 to about 0.5.

Light emitted from the light-emitting element layer 300 and passing through the functional layer 500 may pass through the low-refractive layer 820 and the lens layer LS. For example, as shown in FIGS. 5 and 6, light emitted from the third light-emitting element LED3 and passing through the light transmission layer 530 may pass through the low-refractive layer 820 and the third lens layer LS3. Similarly, light emitted from the first light-emitting element LED1 and passing through the first quantum-dot layer 510 may pass through the low-refractive layer 820 and the first lens layer LS1. Light emitted from the second light-emitting element LED2 and passing through the second quantum-dot layer 520 may pass through the low-refractive layer 820 and the second lens layer LS2.

Light emitted from the light-emitting element layer 300 and passing through the functional layer 500 may be emitted in all directions. Each of the plurality of lenses LSa of the lens layer LS may collect light spreading in all directions into the emission area of each light-emitting element LED, allowing the light to be emitted to the outside without being absorbed by the light-blocking portion BP or other portions. Additionally, the light passing through the surface S1 of the lens layer LS in contact with the low-refractive layer 820 may be refracted due to the difference in refractive indices between the low-refractive layer 820 and the lens layer LS. The difference in the refractive indices between the low-refractive layer 820 and the lens layer LS according to one or more embodiments is in a range of about 0.2 to about 0.75, resulting in a significant change in the light path of light received by the low-refractive layer 820 from the light-emitting elements LED, which may enhance the light gathering effect. Accordingly, the light efficiency of the display device 1 may be improved.

For example, FIG. 7 is a graph showing a refractive index n1 of the low-refractive layer 820 and a refractive index n2 of the third lens layer LS3 according to one or more embodiments of the present disclosure. Light emitted from the third light-emitting element LED3 and passing through the light transmission layer 530 and the low-refractive layer 820 and the third lens layer LS3 may be refracted by the surface S1 where the third lens layer LS3 and the low-refractive layer 820 are in contact with each other. Referring to FIG. 7, for blue light having a center wavelength of about 460 nm, a refractive index of the third lens layer LS3 may be about 1.53 and a refractive index of the low-refractive layer 820 may be about 1.23. The difference in refractive indices between the third lens layer LS3 and the low-refractive layer 820 may be about 0.3. Thus, the structure of the low-refractive layer 820 and the third lens layer LS3 according to one or more embodiments may have an excellent or suitable light gathering effect. The structure of the first lens layer LS1 and the low-refractive layer 820 overlapping with the first light-emitting element LED1, as well as the structure of the second lens layer LS2 and the low-refractive layer 820 overlapping with the second light-emitting element LED2 may have substantially the same structure as the structure of the third lens layer LS3 and the low-refractive layer 820 described above.

FIG. 8 is a plan view of a lens layer LS according to one or more embodiments of the present disclosure, viewed from the direction in which the light is emitted from the light-emitting element LED (e.g., the z-axis direction, also referred to as the z direction (or +z direction), as it is the direction of the arrow illustrating the z-axis in the drawings). Referring to FIG. 8, in one or more embodiments, the plurality of lenses LSa may be entirely arranged in an area corresponding to the light-emitting element LED, and the plurality of lenses LSa may be arranged at regular intervals from each other.

In one or more embodiments, six lenses LSa may be arranged at equal intervals around one of the plurality of lenses LSa. For example, six lenses LSa of the plurality of lenses LSa may be arranged at equal intervals around another lens LSa of the plurality of lenses LSa in a plan view. This, e.g., refers to that in a top-down view, one lens LSa is surrounded by six other lenses LSa. Each of the six other lenses LSa is spaced equally apart from one another, forming a symmetrical pattern. Through this arrangement structure, the plurality of lenses LSa may be arranged adjacent to each other in as many directions as possible.

Although FIG. 8 illustrates that the lens LSa has a circular shape, the present disclosure is not limited thereto. In one or more embodiments, the lens LSa may have a polygon shape with rounded vertices or an ellipse shape.

In one or more embodiments, a distance SD between two adjacent lenses LSa among a plurality of lenses LSa may be in a range of about 2 μm to about 3 μm.

In one or more embodiments, a diameter (or width) CD of each of a plurality of lenses LSa may be in a range of about 3 μm to about 4 μm.

Because each of the plurality of lenses LSa has a diameter (or width) CD within the above ranges, the lens layer LS may include a larger number of lenses LSa for the same area. The light gathering capability may be further improved through the lens layer LS and the low-refractive layer 820.

Referring to FIG. 5, the second passivation layer 830 may be located between the low-refractive layer 820 and the second bank layer 540. The second passivation layer 830 includes, for example, an inorganic material such as silicon oxide, silicon nitride, and/or silicon oxynitride, and may be formed by a chemical vapor deposition method. The second passivation layer 830 may prevent or reduce the occurrence of defects due to impurities, such as gases generated from the first color filter 710, the second color filter 720, and/or the third color filter 730, from entering into the first quantum-dot layer 510, the second quantum-dot layer 520, or the emission layer of the light-emitting element LED underneath. In one or more embodiments, the second passivation layer 830 may not be provided.

As described above, the light-emitting panel 1000 may be formed by sequentially forming the circuit layer 200, the light-emitting element layer 300, the encapsulation layer 400, the functional layer 500, and the first passivation layer 810 on the first substrate 100. The functional layer 500 may be formed by forming the second bank layer 540 on the second inorganic encapsulation layer 430 of the encapsulation layer 400, and then forming the first quantum-dot layer 510, the second quantum-dot layer 520, and the light transmission layer 530. In one or more embodiments, the color filter panel 2000 may be formed by forming the color filter layer 700 on the second substrate 600, forming the lens layer LS on the color filter layer 700, and then sequentially forming the low-refractive layer 820 and the second passivation layer 830.

Thereafter, the light-emitting panel 1000 and the color filter panel 2000 may be bonded by a sealant and/or the like, and a space between them may be filled with the filler 900. The filler 900 may be filled in the space between the light-emitting panel 1000 and the color filter panel 2000.

In one or more embodiment, the low-refractive layer 820 may be arranged between the color filter layer 700 and the lens layer LS on the second substrate 600, and the functional layer 500 on the first substrate 100. For example, the “low-refractive layer” 820 is positioned between the color filter layer 700 and the lens layer LS on the second substrate 600 on one side, and the functional layer 500 on the first substrate 100 on the other side. This refers to that the low-refractive layer 820 is sandwiched between these two sides, helping to manage light refraction and improve the display's visual quality.

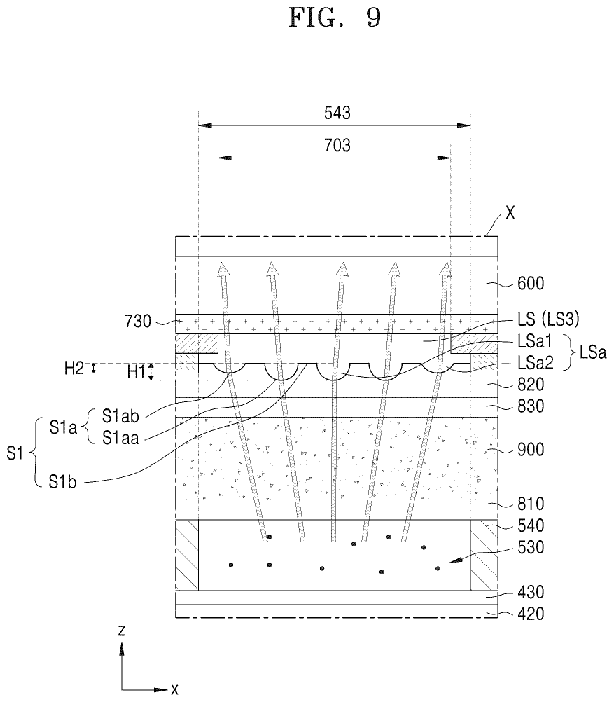

FIG. 9 is a schematic cross-sectional view illustrating a portion of the display device 1 according to one or more embodiments of the present disclosure. FIG. 9 is a modified embodiment of FIG. 6, and is an enlarged cross-sectional view of the region X of FIG. 5, according to one or more embodiments of the present disclosure.

Referring to FIG. 9, a plurality of lenses LSa of the lens layer LS may include a first lens LSa1 and a second lens LSa2. The first lens LSa1 may be arranged at a position corresponding to the center of the light-emitting element LED. The second lens LSa2 may be arranged at a position corresponding to the peripheral portion of the light-emitting element LED. The second lens LSa2 may be arranged closer to the light-blocking portion BP of the color filter layer 700 than the first lens LSa1.

FIG. 9 illustrates that the plurality of lenses LSa include three first lenses LSa1 and two second lenses LSa2, but the present disclosure is not necessarily limited thereto. In one or more embodiments, the number of first lenses LSa1 and second lenses LSa2 may be variously and suitably modified.

A surface S1 of the lens layer LS in contact with the low-refractive layer 820 may include convex surfaces S1a of each of a plurality of lenses LSa and flat surfaces S1b between the convex surfaces S1a. A curvature of a second convex surface S1ab of the second lens LSa2 may be less than a curvature of a first convex surface S1aa of the first lens LSa1. A maximum vertical distance H1 from the flat surface S1b of the lens layer LS to the first convex surface S1aa of the first lens LSa1 may be greater than a maximum vertical distance H2 from the flat surface S1b of the lens layer LS to the second convex surface S1ab of the second lens LSa2.

In one or more embodiments, the first lens LSa1 and the second lens LSa2 of the lens layer LS may be formed in the same process using a halftone mask.

As described above, each of the plurality of lenses LSa of the lens layer LS may gather the light spreading in all directions into the emission area of the corresponding light-emitting element LED. As such, the front luminance of the display device 1 may increase. However, as the curvature of the lens LSa increases, the lateral luminance of the display device 1 may decrease.

According to the present embodiments, the curvature of the second lens LSa2 arranged at a position corresponding to a periphery of the light-emitting element LED may be different from the curvature of the first lens LSa1 arranged at a position corresponding to a center of the light-emitting element LED. The curvature of the second lens LSa2 arranged at the position corresponding to the periphery of the light-emitting element LED may be less than the curvature of the first lens LSa1 arranged at the position corresponding to the center of the light-emitting element LED. The lens layer LS according to the present embodiments may improve the front luminance of the display device 1 and prevent or reduce a decrease in lateral luminance.

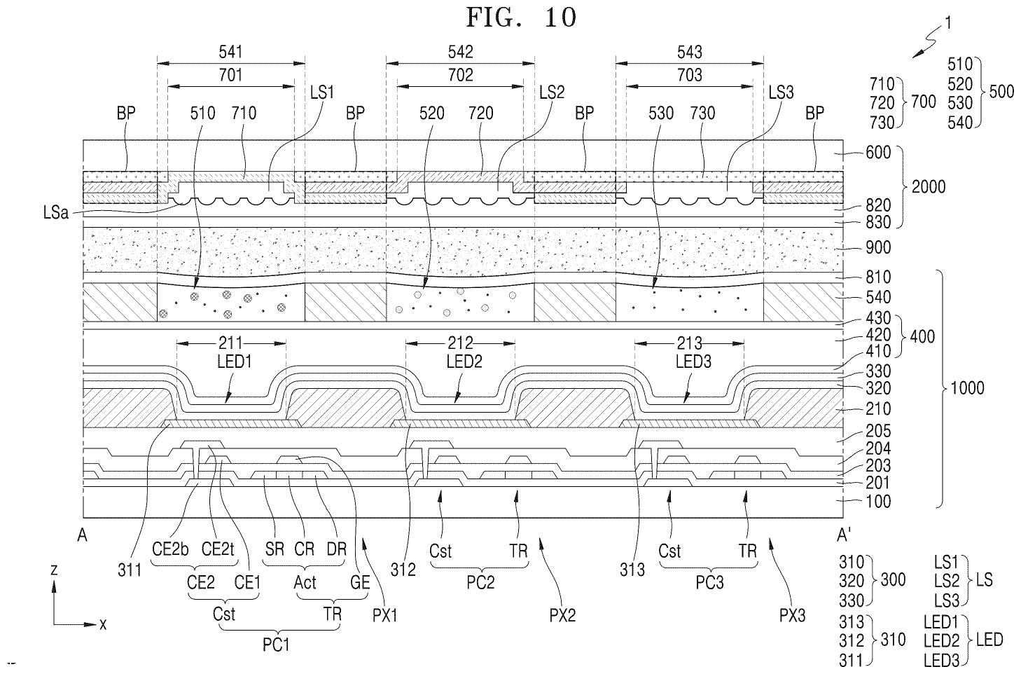

FIG. 10 is a schematic cross-sectional view of a display device taken along the line A-A′ of FIG. 1, according to one or more embodiments of the present disclosure. FIG. 10 is a modified embodiment of FIG. 5, and hereinafter, differences will be mainly described and redundant descriptions may not be provided for conciseness.

Referring to FIG. 10, the first quantum-dot layer 510, the second quantum-dot layer 520, and the light transmission layer 530 of the functional layer 500 may be respectively formed in the first bank opening 541, the second bank opening 542, and the third bank opening 543 defined in the second bank layer 540 after forming the second bank layer 540. Each of the first quantum-dot layer 510, the second quantum-dot layer 520, and the light transmission layer 530 may be formed through an inkjet method.

In one or more embodiments, the first quantum-dot layer 510, the second quantum-dot layer 520, and the light transmission layer 530 may have a concave shape recessed with respect to an upper surface of the second bank layer 540. This may be a result of ink shrinking during a manufacturing process of the functional layer 500.

The first passivation layer 810 may be arranged on the function layer 500. The first passivation layer 810 may be formed to have a substantially uniform thickness overall. The upper surface of the first passivation layer 810 may not be flat and may have a groove corresponding to the concave shape of each of the first quantum-dot layer 510, the second quantum-dot layer 520, and the light transmission layer 530. A surface of the light-emitting panel 1000 facing (e.g., opposite to) the color filter panel 2000 may not be flat and the filler 900 may fill the grooves corresponding to the concave shape of each of the first quantum-dot layer 510, the second quantum-dot layer 520, and the light transmission layer 530.

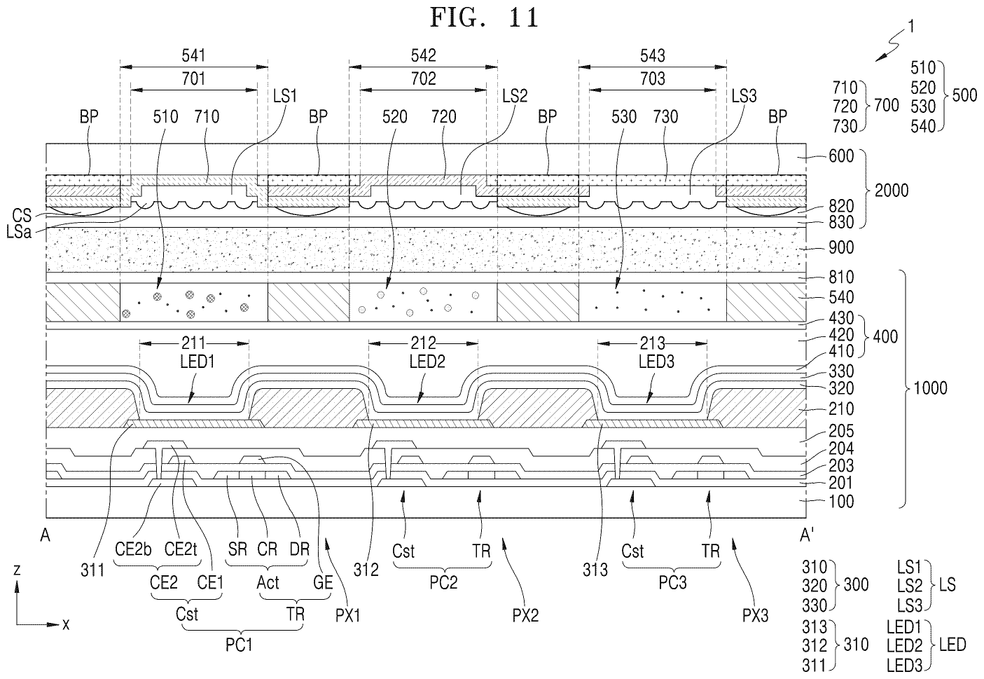

FIG. 11 is a schematic cross-sectional view of a display device taken along the line A-A′ of FIG. 1, according to one or more embodiments of the present disclosure. FIG. 11 is a modified embodiment of FIG. 5, and hereinafter, differences will be mainly described and redundant descriptions may not be provided for conciseness.

Referring to FIG. 11, the color filter panel 2000 may include a spacer CS arranged on the surface of the color filter layer 700 facing (e.g., opposite to) the functional layer 500. The spacer CS may protrude toward the light-emitting panel 1000. The spacer CS may allow the functional layer 500, the color filter layer 700, and the lens layer LS to maintain a certain interval from each other.

The spacer CS may be spaced and/or apart (e.g., spaced apart or separated) from the lens layer LS. In one or more embodiments, a plurality of spacers CS may be provided, and the spacers CS may be spaced and/or apart (e.g., spaced apart or separated) from each other in a direction normal (e.g., perpendicular) to the thickness direction of the lens layer LS and the display device 1. The spacer(s) CS may be arranged on the light-blocking portion BP of the color filter layer 700.

In one or more embodiments, the spacer(s) CS may directly contact the low-refractive layer 820. Additionally, in one or more embodiments, the spacer(s) CS may be in contact with the second passivation layer 830 covering the low-refractive layer 820.

The spacer(s) CS may be concurrently (e.g., simultaneously) formed in the same process as the lens layer LS. The spacer(s) CS and the lens layer LS may be patterned using a single mask. Accordingly, the manufacturing cost of the display device 1 may be reduced and the manufacturing process may be shortened.

The spacer(s) CS may include the same material as the lens layer LS. The spacer(s) CS may include a transparent organic material. In one or more embodiments, the refractive index of the spacer(s) CS may be in a range of about 1.50 to about 1.75. In one or more embodiments, the refractive index of the spacer(s) CS may be in a range of about 1.60 to about 1.70.

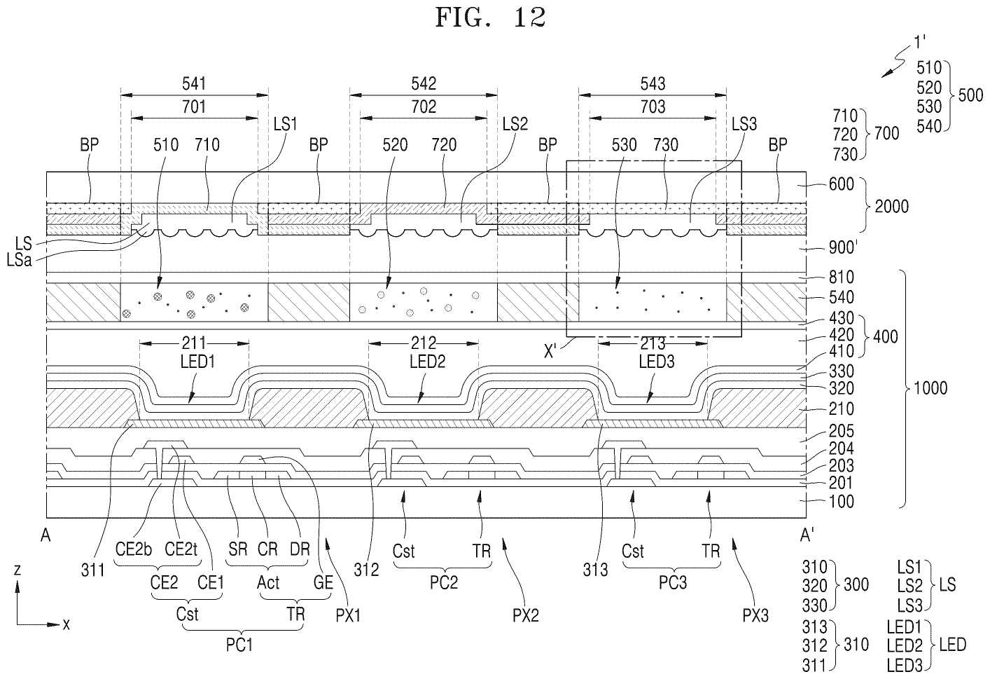

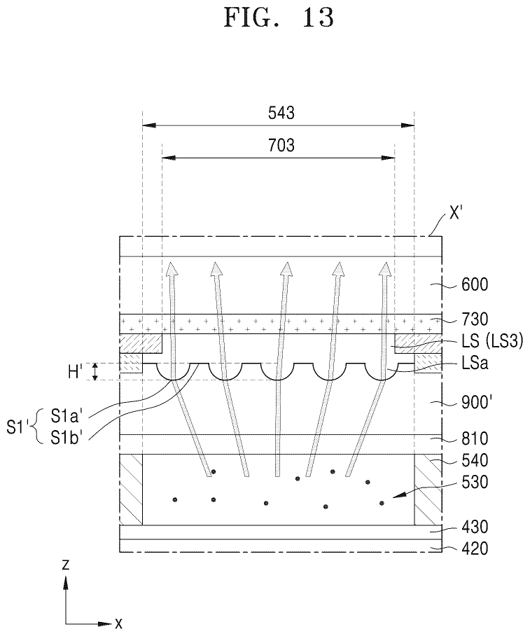

FIG. 12 is a schematic cross-sectional view of a display device 1′ according to one or more embodiments of the present disclosure. FIG. 13 is a schematic cross-sectional view of a portion of the display device 1′, and is an enlarged cross-sectional view of the region X′ of FIG. 12, according to one or more embodiments of the present disclosure. FIGS. 12 and 13 are modified embodiments of FIGS. 5 and 6, and hereinafter, differences will be mainly described and redundant descriptions may not be provided.

Referring to FIGS. 12 and 13, the display device 1′ may include a light-emitting panel 1000 and a color filter panel 2000. In one or more embodiments, the light-emitting panel 1000 of the display device 1′ may include a first substrate 100, a circuit layer 200, a light-emitting device layer 300, an encapsulation layer 400, a function layer 500, and a first passivation layer 810. The color filter panel 2000 of the display device 1′ may include a second substrate 600, a color filter layer 700, and a lens layer LS.

The light-emitting panel 1000 and the color filter panel 2000 may be bonded to each other by a sealant and/or the like. An air gap 900′ may be naturally formed during the bonding process. In one or more embodiments, a manufacturing cost of the display device 1′ including the air gap 900′ may be reduced because a separate filler or a filling process is not used. In one or more embodiments, the air gap 900′ may be filled with a gas from which oxygen or a specific component (e.g., element or compound) is removed, including general air, or a gas to which a specific component (e.g., element or compound) is added.

In one or more embodiments, the lens layer LS may be arranged on the second substrate 600 on a surface of the color filter layer 700 facing (e.g., opposite to) the functional layer 500 on the first substrate 100. The lens layer LS may be spaced and/or apart (e.g., spaced apart or separated) from the first passivation layer 810 with the air gap 900′ located therebetween.

The lens layer LS may correspond to at least one light-emitting element LED. In one or more embodiments, the lens layer LS may include a first lens layer LS1 corresponding to the first light-emitting element LED1, a second lens layer LS2 corresponding to the second light-emitting element LED2, and a third lens layer LS3 corresponding to the third light-emitting element LED3. The lens layer LS may include a plurality of lenses LSa. Each of the plurality of lenses LSa of the lens layer LS may have a convex shape in a direction opposite to the direction of the light emitted from the light-emitting element layer 300 and passing through the functional layer 500.

The air gap 900′ may directly contact the lens layer LS. In one or more embodiments, the air gap 900′ may directly contact a portion of the color filter layer 700. The air gap 900′ may be in direct contact with the first lens layer LS1, the second lens layer LS2, and the third lens layer LS3. The air gap 900′ may be continuously formed over the first lens layer LS1, the second lens layer LS2, and the third lens layer LS3.

Referring to FIG. 13, a surface S1′ contacting the air gap 900′ of the lens layer LS may include convex surfaces S1a′ of each of the plurality of lenses LSa and flat surfaces S1b′ between the convex surfaces S1a′. In one or more embodiments, the convex surfaces S1a′ of each of the plurality of lenses LSa may have the same curvature.

In one or more embodiments, a maximum vertical distance H′ from the flat surface S1b′ of the lens layer LS to the convex surface S1a′ of one lens LSa among the plurality of lenses LSa may be same as the maximum vertical distance H′ from the flat surface S1b′ of the lens layer LS to the convex surface S1a′ of another lens LSa among the plurality of lenses LSa. However, the present disclosure is not necessarily limited thereto. In one or more embodiments, the convex surface S1a′ of each of at least some lenses LSa among the plurality of lenses LSa may have a different curvature than the convex surface S1a′ of each of the other lenses LSa among the plurality of lenses LSa. The maximum vertical distance from the flat surface S1b′ of the lens layer LS to at least some of the convex surfaces S1a′ of the multiple lenses LSa may differ from the maximum vertical distance from the flat surface S1b′ of the lens layer LS to other convex surfaces S1a′.

The lens layer LS may include a transparent organic material. In one or more embodiments, a refractive index of the lens layer LS may be in a range of about 1.50 to about 1.75. In one or more embodiments, the refractive index of the lens layer LS may be in a range of about 1.60 to about 1.70.

A refractive index of the air gap 900′ may be less than the refractive index of the low-refractive layer 820 of FIG. 5. The refractive index of the air gap 900′ may be less than the refractive index of the lens layer LS. In one or more embodiments, a difference between the refractive index of the lens layer LS and the refractive index of the air gap 900′ may be in a range of about 0.2 to about 0.75. In one or more embodiments, the difference between the refractive index of the lens layer LS and the refractive index of the air gap 900′ may be in a range of about 0.5 to about 0.75. Thus, in FIG. 12, the air gap 900′ includes a layer of air with a low-refractive index, thus serving the same function as the low-refractive layer 820 of FIG. 5, for example.

As described above, light emitted from the light-emitting element layer 300 and passing through the functional layer 500 may be emitted in all directions. Each of the plurality of lenses LSa of the lens layer LS may collect light spreading in all directions into the emission area of each light-emitting element LED, allowing the light to be emitted to the outside without being absorbed by the light-blocking portion BP or other areas. Furthermore, the light passing through the surface S1′ in contact with the air gap 900′ of the lens layer LS may be refracted due to the difference in refractive indices between the air gap 900′ and the lens layer LS on the surface S1′. The difference in the refractive indices between the air gap 900′ and the lens layer LS according to the present embodiments may be in a range of about 0.2 to about 0.75, resulting in a significant change in the light path of light emitted from the light-emitting elements LED and received by the lens layer LS, which may enhance a light gathering effect. Accordingly, the light efficiency of the display device 1′ may be improved.

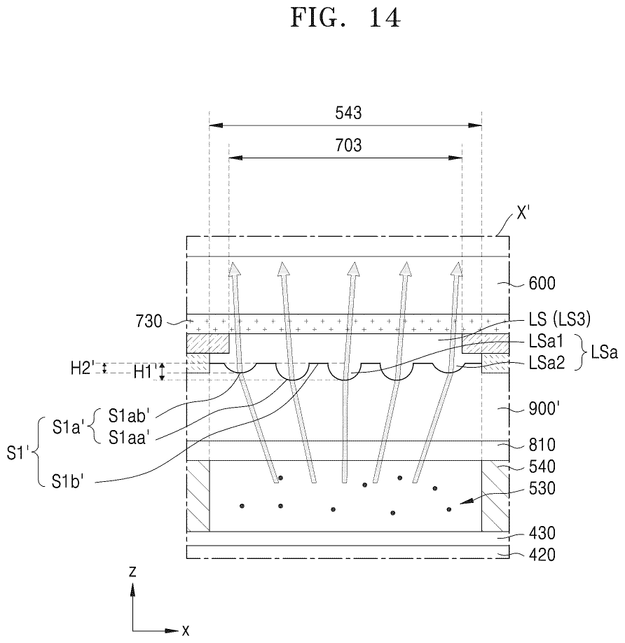

FIG. 14 is a schematic cross-sectional view illustrating a portion of the display device 1′, according to one or more embodiments of the present disclosure. FIG. 14 is a modified embodiment of FIG. 13 and shows an enlarged cross-sectional view of the region X′ of FIG. 12, according to one or more embodiments of the present disclosure. Hereinafter, differences will be mainly described and redundant descriptions may not be provided for conciseness.

Referring to FIG. 14, a plurality of lenses LSa of the lens layer LS may include a first lens LSa1 and a second lens LSa2. The first lens LSa1 may be arranged at a position corresponding to a center of the light-emitting element LED. The second lens LSa2 may be arranged at a position corresponding to a peripheral portion of the light-emitting element LED. The second lens LSa2 may be arranged closer to the light-blocking portion BP of the color filter layer 700 than the first lens LSa1.

FIG. 14 illustrates that the plurality of lenses LSa include three first lenses LSa1 and two second lenses LSa2, but the present disclosure is not necessarily limited thereto. In one or more embodiments, the number of first lenses LSa1 and second lenses LSa2 may be variously and suitably modified.

A surface S1′ contacting the air gap 900′ of the lens layer LS may include convex surfaces S1a′ of each of the plurality of lenses LSa and flat surfaces S1b′ between the convex surfaces S1a′. A curvature of a second convex surface S1ab′ of the second lens LSa2 may be less than a curvature of a first convex surface S1aa′ of the first lens LSa1. A maximum vertical distance H2′ from the flat surface S1b′ of the lens layer LS to the second convex surface S1ab′ of the second lens LSa2 may be less than a maximum vertical distance H1′ from the flat surface S1b′ of the lens layer LS to the first convex surface S1aa′ of the first lens LSa1.

In one or more embodiments, the first lens LSa1 and the second lens LSa2 of the lens layer LS may be formed in the same process using a halftone mask.

As described above, each of the plurality of lenses LSa of the lens layer LS may gather the light spreading in all directions into the emission area of the corresponding light-emitting element LED. Thus, the front luminance of the display device 1′ may increase. However, as the curvature of the lens LSa increases, the lateral luminance of the display device 1′ may decrease.

However, according to the present embodiments, the curvature of the second lens LSa2 arranged on the position corresponding to the periphery of the light-emitting element LED may be designed to be different from the curvature of the first lens LSa1 arranged at the position corresponding to the center of the light-emitting element LED. A curvature of the second lens LSa2 arranged at a position corresponding to the periphery of the light-emitting device LED may be less than a curvature of the first lens LSa1 arranged at a position corresponding to the center of the light-emitting device LED. The lens layer LS according to the present embodiments may improve the front luminance of the display device 1′ and prevent or reduce a decrease in the lateral luminance.

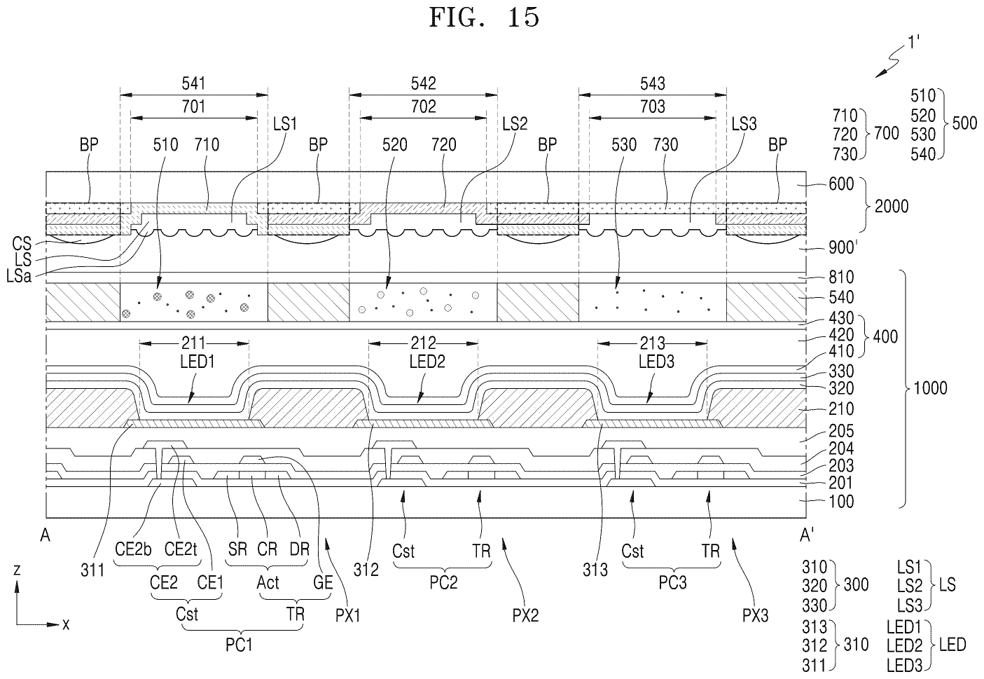

FIG. 15 is a schematic cross-sectional view of the display device 1′ according to one or more embodiments of the present disclosure. FIG. 15 is a modified embodiment of FIG. 12, and hereinafter, the differences will be mainly described and redundant descriptions may not be provided for conciseness.

Referring to FIG. 15, the color filter panel 2000 may include a spacer CS arranged on the surface of the color filter layer 700 facing (e.g., opposite to) the functional layer 500. The spacer CS may protrude toward the light-emitting panel 1000. The spacer CS may allow the functional layer 500, the color filter layer 700, and the lens layer LS to maintain a certain interval.

The spacer CS may be spaced and/or apart (e.g., spaced apart or separated) from the lens layer LS. In one or more embodiments, a plurality of spacers CS may be provided, and the spacers CS may be spaced and/or apart (e.g., spaced apart or separated) from each other in a direction normal (e.g., perpendicular) to the thickness direction of the lens layer LS and the display device 1′. The spacer(s) CS may be arranged on the light-blocking portion BP of the color filter layer 700.

In one or more embodiments, the spacer(s) CS may directly contact the air gap 900′.

The spacer(s) CS may be concurrently (e.g., simultaneously) formed in the same process as the lens layer LS. The spacer(s) CS may include the same material as the lens layer LS. The spacer(s) CS may include a transparent organic material. In one or more embodiments, a refractive index of the spacer(s) CS may be in a range of about 1.50 to about 1.75. In one or more embodiments, the refractive index of the spacer(s) CS may be in a range of about 1.60 to about 1.70.

The display device according to the embodiment may be applied to various electronic devices. An electronic device according to an embodiment of the present disclosure may include the display device (e.g., the display device of FIG. 1) described above, and may further include modules or apparatuses having additional functions in addition to the display device.

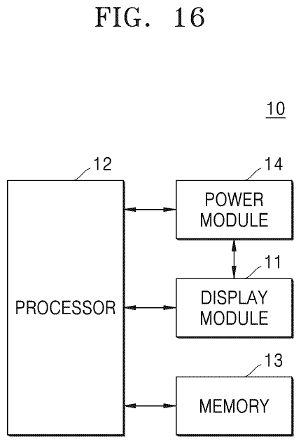

FIG. 16 is a block diagram of an electronic device according to one or more embodiments.

Referring to FIG. 16, an electronic device 10 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process a signal received and output image information through a display screen.

The power module 14 may include a power supply module such as a power adapter or a battery device, and a power conversion module that converts the power supplied by the power supply module to generate power necessary for the operation of the electronic device 10.

At least one of the components of the electronic device 10 described above may be included in the display device according to the embodiments described above. In addition, a part among the individual modules functionally included in one module may be included in the display device, and another part may be provided separately from the display device. For example, the display device may include the display module 11, and the processor 12, the memory 13, and the power module 14 may be provided in the form of other apparatuses within the electronic device 10 except for the display device.

In an embodiment, the display module 11 included in the display device may drive based on the image data signal and the input control signal received from the processor 12.

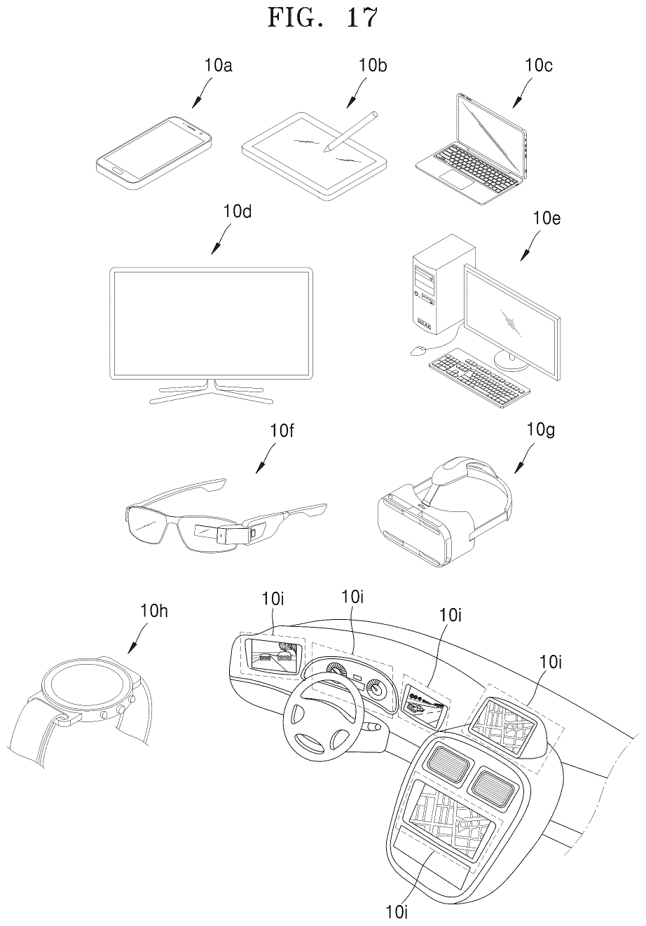

FIG. 17 is schematic diagrams of electronic devices according to various embodiments.

Referring to FIG. 17, various electronic devices to which display devices according to embodiments are applied may include not only image display electronic devices such as a smart phone 10a, a tablet PC 10b, a laptop 10c, a TV 10d, and a desk monitor 10e, but also a wearable electronic device including display modules such as smart glasses 10f, a head mounted display 10g, and a smart watch 10h, and a vehicle electronic device 10i including a dashboard, a center fascia, and display modules such as a CID (Center Information Display) and a room mirror display disposed in the dashboard.

According to one or more embodiments described above, a display device with improved light efficiency may be provided. However, the scope of the present disclosure is not limited thereto.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “approximately,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a first substrate;
a second substrate opposite to the first substrate;
a light-emitting element layer on the first substrate and comprising at least one light-emitting element;
an encapsulation layer on the light-emitting element layer and comprising at least one inorganic encapsulation layer and at least one organic encapsulation layer;
a functional layer on the encapsulation layer and comprising at least one of a quantum dot or a scattering particle;
a color filter layer on a surface of the second substrate facing the first substrate;
a lens layer on a surface of the color filter layer facing the functional layer and corresponding to the at least one light-emitting element; and
a low-refractive layer between the functional layer on the first substrate and the color filter layer and the lens layer on the second substrate.

2. The display device of claim 1,
wherein the low-refractive layer is in direct contact with the lens layer, and
wherein a refractive index of the low-refractive layer is less than a refractive index of the lens layer.

3. The display device of claim 1,
wherein a difference between a refractive index of the lens layer and a refractive index of the low-refractive layer is in a range of about 0.2 to about 0.75.

4. The display device of claim 1,
wherein the lens layer comprises a plurality of lenses, and
wherein each of the plurality of lenses has a convex shape in a direction opposite to a direction from which light is to be emitted from the at least one light-emitting element.

5. The display device of claim 4,
wherein a surface of the lens layer in contact with the low-refractive layer comprises convex surfaces of the plurality of lenses and flat surfaces between the convex surfaces.

6. The display device of claim 4,
wherein six lenses of the plurality of lenses are arranged at equal intervals around another lens of the plurality of lenses in a plan view.

7. The display device of claim 4,
wherein an interval between two adjacent lenses among the plurality of lenses is in a range of about 2 μm to about 3 μm.

8. The display device of claim 4,
wherein a diameter of each of the plurality of lenses is in a range of about 3 μm to about 4 μm.

9. The display device of claim 5,
wherein the plurality of lenses comprise a first lens at a center of the at least one light-emitting element in a plan view and a second lens at a periphery of the at least one light-emitting element in a plan view.

10. The display device of claim 9,
wherein a curvature of a convex surface of the second lens is less than a curvature of a convex surface of the first lens.

11. The display device of claim 1,
wherein the encapsulation layer comprises a first inorganic encapsulation layer, an organic encapsulation layer, and a second inorganic encapsulation layer, which are sequentially arranged, and
wherein the functional layer is in direct contact with the second inorganic encapsulation layer.

12. The display device of claim 1,
wherein the light-emitting element layer comprises a first light-emitting element, a second light-emitting element, and a third light-emitting element, and
wherein the functional layer comprises a first quantum-dot layer corresponding to the first light-emitting element, a second quantum-dot layer corresponding to the second light-emitting element, and a light transmission layer corresponding to the third light-emitting element.

13. The display device of claim 12,
wherein the color filter layer comprises a first color filter corresponding to the first light-emitting element, a second color filter corresponding to the second light-emitting element, and a third color filter corresponding to the third light-emitting element, and
wherein at least two color filters selected from among the first color filter, the second color filter, and the third color filter overlap each other to define a light-blocking portion.

14. The display device of claim 13,
wherein the lens layer comprises a first lens layer corresponding to the first light-emitting element, a second lens layer corresponding to the second light-emitting element, and a third lens layer corresponding to the third light-emitting element, and
wherein the first lens layer, the second lens layer, and the third lens layer do not overlap the light-blocking portion of the color filter layer.

15. The display device of claim 1,
further comprising a spacer on the surface of the color filter layer facing the functional layer,
wherein the spacer comprises the same material as the lens layer.

16. The display device of claim 1,
further comprising a filler between the low-refractive layer and the functional layer.

17. The display device of claim 16, further comprising:
a first passivation layer between the functional layer and the filler; and
a second passivation layer between the low-refractive layer and the filler.

18. The display device of claim 1, wherein the low-refractive layer is a layer of air defining an air gap between the lens layer and the functional layer.

19. An electronic device comprising:
a display device comprising:
a first substrate;
a second substrate opposite to the first substrate;
a light-emitting element layer on the first substrate and comprising at least one light-emitting element;
an encapsulation layer on the light-emitting element layer and comprising at least one inorganic encapsulation layer and at least one organic encapsulation layer;
a functional layer on the encapsulation layer and comprising at least one of quantum dots or scattering particles;
a color filter layer on a surface of the second substrate facing the first substrate;
a lens layer on a surface of the color filter layer facing the functional layer and corresponding to the at least one light-emitting element; and
a low-refractive layer between the functional layer on the first substrate and the color filter layer and the lens layer on the second substrate.

20. The electronic device of claim 19, further comprising:
a display module;
a processor;
a power module; and
a memory,
wherein the display device includes one of the display module, the processor, the power module, or the memory.
